(19) United States
(12) Patent Application Publication
(10) Pub. No.: US 2012/0160297 A1
(43) Pub. Date: Jun. 28, 2012

(54) SOLAR POWER GENERATION SYSTEM AND POWER LINES FOR SOLAR POWER GENERATION SYSTEM

(76) Inventors: Akiko Yamakawa, Osaka-shi (JP); Ryo Iwai, Osaka-shi (JP); Akira Shimizu, Osaka-shi (JP)

(21) Appl. No.: 13/262,017

(22) PCT Filed: Mar. 25, 2010
(86) PCT No.: PCT/JP2010/055245

§ 371 Date: Mar. 12, 2012

(30) Foreign Application Priority Data
Mar. 31, 2009 (JP) 2009-087500

(51) Int. Cl. H01L 31/05; H02H 5/04

(52) U.S. Cl. 136/244; 361/104

(57) ABSTRACT

It is an object to provide an overcurrent protecting device to branch lines branched from a trunk line and to make it easy to check the overcurrent protecting device. A solar power generation system includes an electric power extracting trunk line having a plurality of solar cell strings interconnected in parallel; a plurality of branch lines that connect the solar cell strings to the trunk line, and an overcurrent protecting device connected between the branch line and the solar cell string.

### TECHNICAL FIELD

The present invention relates to a solar power generation system for parallelly interconnecting a plurality of solar cell modules or a plurality of solar cell strings in each of which a plurality of solar cell modules are interconnected in series. In particular, the present invention relates to a solar power generation system including overcurrent protecting devices for solar cell strings each obtained by connecting a solar cell module or a plurality of solar cell modules and to power lines for the solar power generation system.

### BACKGROUND ART

By a solar power generation system in which a plurality of solar cell strings obtained by connecting a plurality of solar cell modules are interconnected in series are interconnected in parallel, a large-scale power plant ranging in scale from several dozen kilowatts to several dozen megawatts is constructed. Such a solar power generation system is required to include overcurrent protecting devices in solar cell strings, respectively. For example, in construction of a 1-megawatt solar power generation system, when a solar cell string obtained by interconnecting two solar cell modules each having an output of 121 W and an output voltage of 240 V in series is used, 4133 solar cell strings are necessary, and the solar cell strings are required to include overcurrent protecting devices, respectively. When one solar cell string has a width of about 1 m, the length of the solar cell strings that horizontally align is 4133 m. Thus, a monthly or annual check for the solar power generation system or a check in an abnormal state such as a decreased output takes a lot of trouble and a long time. When a rated output voltage of a solar cell string is low, a fuse sealed in a transparent glass tube can be used for an overcurrent protecting device. When the fuse sealed in the transparent glass tube is used, fusing of the fuse can be detected by an appearance check. However, in solar cell strings that output a high voltage of 100 V or higher, ceramics tube fuses are used to suppress sparks from being generated between the terminals of fuses when the fuses are fused or after the fuses are fused. An arc-extinguishing material may be sealed in the ceramics tube fuse to suppress sparks from being generated. In this manner, fusing of the ceramics tube fuse or the arc-extinguishing-material-including fuse cannot be observed from the outside. For this reason, a check needs to be executed by using a clamp ammeter or the like in the daytime in which the solar cell strings generate electric powers, or the fuse is removed and subjected to a burn-in test with a tester.

A branched cable having a fuse incorporated therein is known by Unexamined Japanese Patent Publication No. 2008-226621 and Unexamined Japanese Patent Publication No. 2002-334648. Unexamined Japanese Patent Publication No. 2008-226621 discloses a cable for illumination in a tunnel. The branch cable includes a main cable connected to a power supply and a plurality of branch lines branched from the main cable. Sockets are arranged on distal ends of the branch lines, and plugs to which panel lamps in tunnel are connected are fitted in the sockets, respectively, to supply a power source to the panel lamps in tunnel. The branch cable has fuses incorporated in the sockets or the plugs. In this manner, even though one panel lamp is broken down, a stable electric power can be supplied to the other loads.

Unexamined Japanese Patent Publication No. 2002-334648 discloses a branched connector with fuse holder. In this branch connector, a fuse holder terminal portion of a trunk line terminal is held in a fuse holder chamber, and a clamping terminal portion of the trunk line terminal is held in a trunk line clamping chamber. A fuse holder portion of a branch line terminal is held in the fuse holder chamber, and a clamping terminal portion of the branch line terminal is held in the branch line clamping chamber to obtain a structure. With this structure, a fuse holder can also be held in a small place.

It is known by Unexamined Japanese Utility-model Publication No. sho62(1987)-183379 that a fusing portion is covered with a transparent protector to make it possible to check fusing of a fuse. Furthermore, it is also known that heat-sensitive paper is wound on a fuse to make it possible to visually check fusing of the fuse.

### SUMMARY OF THE INVENTION

### Problems to be Solved by the Invention

According to Unexamined Japanese Patent Publication No. 2008-226621 and Unexamined Japanese Patent Publication No. 2002-334648, a fuse is held in a socket, a plug, or a fuse holder. Thus, it cannot be visually checked from the outside whether a fuse is fused. For this reason, the socket, the plug, or the fuse holder needs to be opened to check the fuse.

In Unexamined Japanese Utility-model Publication No. sho62(1987)-183379, fusing of a fuse can be visually checked from the outside. However, the fuse is for low voltage and is not for a solar cell string that generates a high voltage. The fuse for high voltage or high current is a fine ceramic fuse. Fusing of the fuse cannot be checked by an appearance check.

Since a large-scale power plant supplies electric powers to commercial-scale utility customers such as regions or factories, output powers are not allowed from decreasing due to fusing of overcurrent protecting devices, and insufficiency of power supplies is not allowed. For this reason, a periodic check or a check in an abnormal state is performed. However, a check for a large-scale power plant takes a lot of trouble and a long time as described above.

In consideration of the above problem, it is an object of the present invention to provide an overcurrent protecting device to a branch line branched from a trunk line to connect the overcurrent protecting device to a position that is close to a solar cell string to make it possible to make easy to check the overcurrent protecting device. It is another object to reduce cost of wiring in a solar cell system and to simplify wiring works.

### Solution to the Problems

In order to solve the above problem, a solar power generation system according to the present invention includes: an electric power extracting trunk line having a plurality of branch lines interconnected in parallel, solar cell modules or solar cell strings connected to the branch lines, and overcurrent protecting devices that connect overcurrent protecting elements fused by overcurrents flowing in the solar cell strings or the branch lines between the branch lines and the solar cell modules or to parts of the solar cell strings.

In the present invention, the solar cell string is configured by connecting a plurality of solar cell modules in series, and a large-scale power plant is constructed by a solar power generation system obtained by interconnecting a large number of solar cell strings in parallel. The large-scale power plant is used as a regional electric power plant in place of a thermal power plant, an atomic power plant, or a hydraulic power plant. Alternatively, according to the present invention, an electric power can be supplied to a commercial-scale utility customers such as factories, and the commercial-scale utility customers can have private power generation. In the solar power generation system according to the present invention, a large number of solar cell strings are aligned and installed in a solar power generation facility. Furthermore, in the solar power generation system according to the present invention, since the solar cell strings are aligned and installed to make it possible to visually check the overcurrent protecting devices from the outside, the states of the overcurrent protecting devices can be checked at places near the solar cell strings.

In the solar power generation system according to the present invention, each of the overcurrent protecting devices includes a fuse that is disconnected when a current not less than a predetermined current flows in the corresponding branch line, and the disconnection of the fuse can be visually checked. In this manner, since an inspection can be performed by a visual check, the inspection can be quickly performed not only in the daytime but also in the nighttime or on a cloudy day. Thus, in a large-scale solar power generation system, troubles and time can be saved.

In particular, since a color fixing agent or a temperature-sensitive agent is sealed in a vessel of the overcurrent protecting device, or heat-sensitive paper is wound on the overcurrent protecting devices such that the heat-sensitive paper can be seen from the outside, the temperature-sensitive agent or the heat-sensitive paper changes in color by heat generating when the fuse is melted. For this reason, the overcurrent protecting device having the fused fuse has a color different from that of a normal overcurrent protecting device, and can be visually checked.

In the solar power generation system according to the present invention, the branch line preferably has a connector, and the overcurrent protecting device is preferably replaceably connected by the connector. With this structure, the overcurrent protecting device having the fused fuse can be easily removed from the corresponding branch line and replaced with a new overcurrent protecting device.

The overcurrent protecting device is desirably installed at an almost eye level on a rear surface side of a solar cell panel. In this manner, an examiner can visually check the overcurrent protecting devices while standing. For this reason, the examiner can check fusing of the fuses while moving on the rear surface sides of solar cell panels.

Furthermore, according to the present invention, there is provided a solar power generation system including an abnormality detecting unit for an overcurrent protecting device operated by an electric power generated by a solar cell string, wherein, when the solar cell string and the overcurrent protecting device are normal, the abnormal detecting unit periodically establishes communication, and, when the solar cell string or the overcurrent protecting device is abnormal, the abnormality detecting unit is not allowed to establish communication. In this manner, the solar power generation system can detect abnormality of each of the solar cell strings and the overcurrent protecting devices by the presence/absence of communication.

According to the present invention, there are provided power lines for the solar power generation system including: a power extracting trunk line having a plurality of branch lines interconnected in parallel; and overcurrent protecting devices to which overcurrent protecting elements fused by overcurrents flowing in the branch lines are connected at at least one ends of the branch lines, wherein solar cell strings are interconnected in parallel.

In this manner, in the solar power generation system, an abnormal portion of the solar cell strings and the overcurrent protecting devices can be easily replaced.

### Effects of the Invention

In the solar power generation system and the power lines for the solar power generation system according to the present invention, since the overcurrent protecting device is connected to the branch line that connects the solar cell string to the power extracting trunk line, a checking operation for the overcurrent protecting device can be performed near the solar cell string. Since disconnection of the fuse can be visually checked, a visual inspection can be quickly performed. Thus, in a large-scale solar power generation system, troubles and time can be saved. For this reason, when abnormality of an overcurrent protecting device is detected, abnormality of a solar cell string can be early detected.

### BRIEF DESCRIPTION OF THE DRAWINGS

FIG. 1 is a block diagram of Embodiment 1 of a solar power generation system of the present invention.

FIG. 2 is an explanatory diagram showing a trunk line employed for the solar power generation system of the present invention.

FIG. 3 is a wiring diagram between solar cell modules constituting the solar power generation system of the present invention.

FIG. 4 is a diagram of a connector employed for the solar power generation system of the present invention.

FIG. 5 is a diagram showing another example of the connector employed for the solar power generation system of the present invention.

FIG. 6 is a perspective view, a plan view, a sectional view, and a circuit diagram of a branch line connection unit employed for the solar power generation system of the present invention.

FIG. 7 is a connection diagram of a solar cell module and a blocking diode that constitute the solar power generation system of the present invention.

FIG. 8 is a diagram for explaining a connection structure of the solar power generation system of the present invention.

FIG. 9 is a diagram for explaining details of a first example of the solar power generation system of the present invention.

FIG. 10 is a diagram for explaining details of a connection unit and a terminal box in the first example of the solar power generation system of the present invention.

FIG. 11 is a diagram for explaining details of a second example of the solar power generation system of the present invention.

FIG. 12 is a diagram for explaining details of a connection unit and a terminal box in the second example of the solar power generation system of the present invention.

FIG. 13 is a diagram for explaining a modification of the second example of the solar power generation system of the present invention.

FIG. 14 is another wiring diagram between solar cell modules constituting the solar power generation system of the present invention.

FIG. 15 is an installation diagram of the solar power generation system of the present invention.

FIG. 16 is a circuit diagram for detecting a failure of an overcurrent protecting device in the solar power generation system of the present invention.

FIG. 17 is a plan view and a sectional view of a first solar cell module constituting the solar power generation system of the present invention.

FIG. 18 is a circuit diagram of a first solar cell module constituting the solar power generation system of the present invention.

FIG. 19 is a diagram showing the relationship between short-circuit resistances Rsh and Prsh, when the short-circuit resistance Rsh varies, of a first solar cell module constituting the solar power generation system of the present invention.

FIG. 20 is a diagram illustrating distribution of the short-circuit resistance Rsh of a first solar cell module constituting the solar power generation system of the present invention.

FIG. 21 is a block diagram of Embodiment 2 of the solar power generation system of the present invention.

FIG. 22 is a block diagram of Embodiment 3 of the solar power generation system of the present invention.

FIG. 23 is an explanatory diagram of detecting a short-circuit fault in the solar power generation system of the present invention.

FIG. 24 is an explanatory diagram of detecting an open-circuit fault in the solar power generation system of the present invention.

### MODE FOR CARRYING OUT THE INVENTION

### Embodiments of the Invention

### Embodiment 1

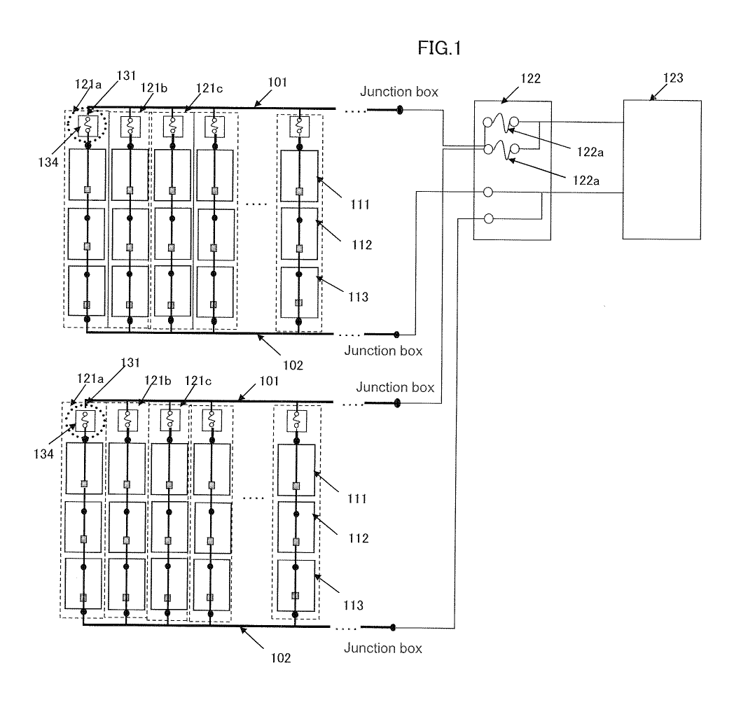

FIG. 1 is a block diagram of Embodiment 1 of the present invention. As shown in FIG. 1, three solar cell modules 111, 112, and 113 are interconnected in series to construct a solar cell string 121. A plurality of solar cell strings 121a, 121b, 121c, . . . are interconnected in parallel across trunk lines 101 and 102 to be connected to an input side of a junction box 122. The trunk lines 101 and 102 are divided into a plurality of groups, and the trunk lines 101 and 102 of the groups are connected to the junction box 122. The junction box 122 includes a fuse 122a and has an output connected to a power conversion device 123, for example, a DC/AC converter (inverter) to supply power to a load. Otherwise, it may be connected to a commercial power line to form grid connection.

In the present invention, a large number of solar cell strings are aligned and installed in a solar power generation facility that constructs a large-scale solar power generation system. In the present invention, overcurrent protecting devices are arranged between the solar power generation system branch lines and the solar cell string, and the overcurrent protecting device are installed such that the overcurrent protecting devices can be seen by an examiner being in a place where a solar cell installed. For this reason, a state of the overcurrent protecting device can be checked at a place close to each of the solar cell strings.

The present invention is featured by including the trunk lines 101 and 102 to which the plurality of solar cell strings 121a, 121b, 121c, . . . are interconnected in parallel and from which an electric power is extracted, a plurality of branch lines 131 connected to the trunk lines 101 and 102, and overcurrent protecting devices 134 connected between the branch lines 131 and the solar cell strings 121.

Though FIG. 1 shows a solar power generation system in which a plurality of solar cell strings 121 each including the three solar cell modules 111, 112, and 113 interconnected in series are interconnected in parallel, the number of the solar cell modules and the solar cell strings may be one or more and is not limited. A required number of solar cell modules or solar cell strings can be connected ranging from a small-scale power plant to a large-scale power plant. For example, when a 1-megawatt large-scale power plant is to be constructed, 4133 solar cell strings in each of which two solar cell modules each having an output of 121 W are interconnected in series are required. Solar cell modules M will be described in detail from <first thin-film solar cell module> to <fourth thin-film solar cell module>.

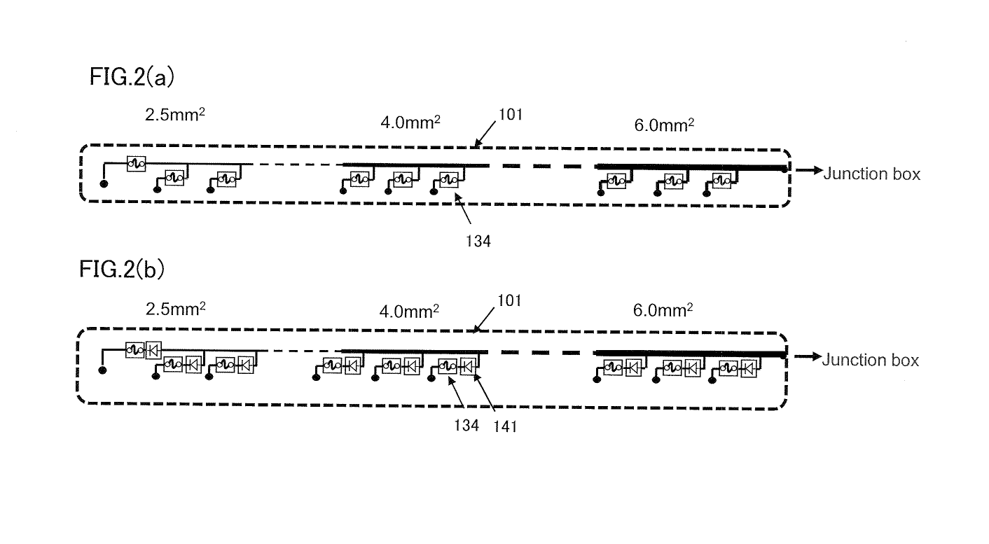

A plurality of solar cell strings are interconnected in parallel. As increasing the interconnection number of the solar cell strings, a current next to the junction box 122 becomes great. For this reason, copper wires for the trunk lines 101 and 102 are used which are different in diameter having a sectional area of 6.0 mm² to 2.0 mm² in turn next to the junction box 122, according to the number of the solar cell strings interconnected. FIG. 2 shows this situation in which as increasing the interconnection number of the solar cell strings, the trunk lines are used which have a sectional area of 5.5 mm² to 6.0 mm² at the junction box 122 side starting from the point that the current is 30 A or more, the lines are used which have a sectional area of 3.5 mm² to 4.0 mm² at the junction box 122 side starting from the point that the current is 20 A or more, and they are used which have a sectional area of 2.0 mm² to 2.5 mm² at the junction box 122 side starting from the point that the current is 10 A or more. Thus, the trunk lines 101 and 102 may be different in thickness. These current values and the thickness of these wires are only exemplified and the above values are not strictly limited to, because it is necessary to allow a little safety margin. FIG. 2(a) is an example in which the plurality of branch lines 131 have the overcurrent protecting devices 134, respectively, and FIG. 2(b) is an example in which the plurality of branch lines 131 have series connections composed of the overcurrent protecting devices 134 and blocking diodes 141, respectively. When an electric energy to be input to a power converter is considered to be constant, the larger generated outputs from the solar cell modules or the solar cell strings connected to the branch lines 131 become, the shorter the length of a power line cable connected to the power converter can be.

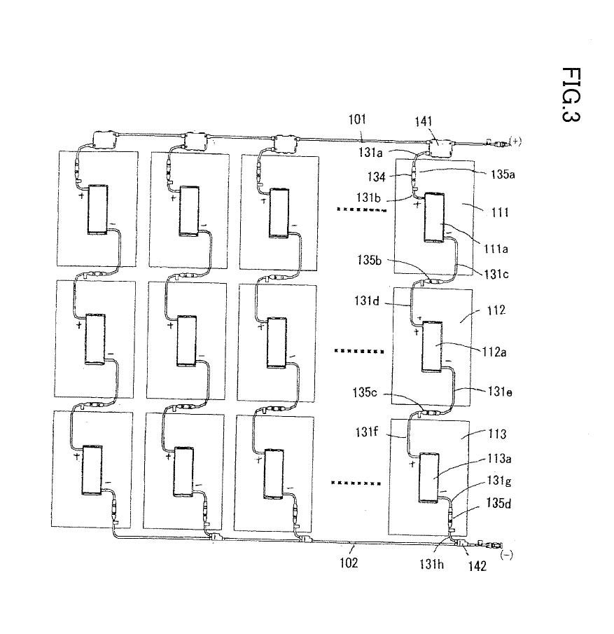

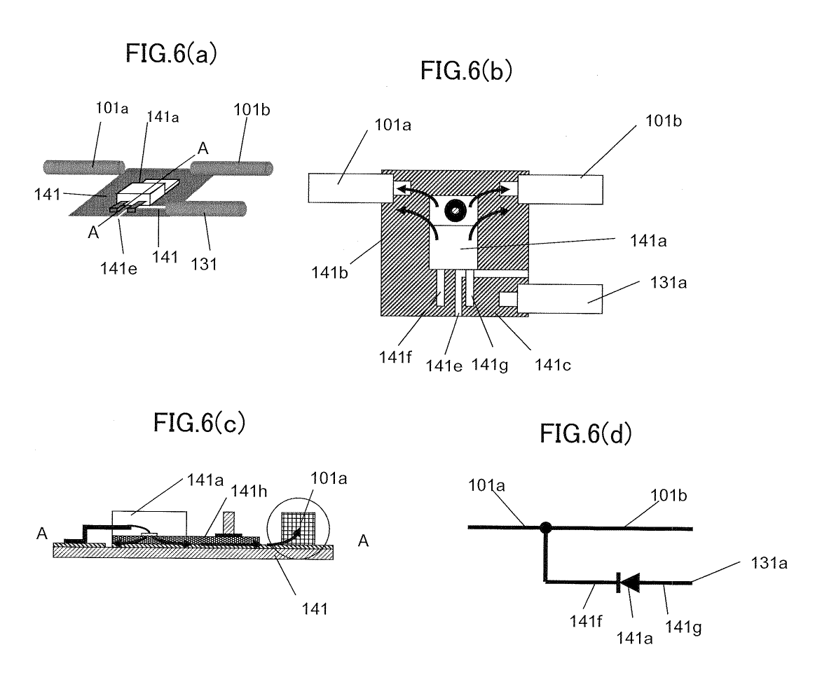

FIG. 3 is a connection diagram between the power extracting trunk lines 101 and 102, branch line connection units 141 and 142, the branch lines 131, connectors 135, the overcurrent protecting devices 134, and solar cell modules 111 to 113. As shown in FIG. 3, a branch line 131a is branched from power extracting trunk line 101 by the branch line connection unit 141 and connected to a connector 135a. The branch connection unit 141 will be described in detail with reference to FIG. 6. The connector 135a has the overcurrent protecting device 134, and is connected to a +terminal of a terminal unit 111a of the solar cell module 111 by an output line 131b. A −terminal of the solar cell module 111 is connected to a terminal unit 112a of the next solar cell module 112 by an output line 131c, a connector 135b, and an output line 131d. A −terminal of the solar cell module 112 is connected to a terminal unit 113a of the next solar cell module 113 by an output line 131e, a connector 135c, and an output line 131f. A −terminal of the solar cell module 113 is connected to the branch line connection unit 142 via an output line 131g, a connector 135d, and an output line 131h and furthermore is connected to the electric power extracting trunk line 102.

Though FIG. 3 illustrates the overcurrent protecting device 134 connected to only the connector 135a, the overcurrent protecting device 134 may be connected to the connectors 135b, 135c, and 135d or may be connected to any one portion in the solar cell string as a part of the solar cell string.

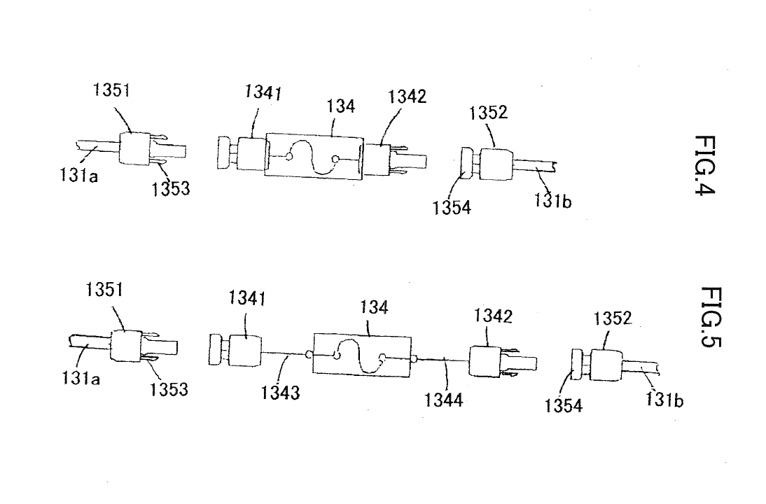

FIG. 4 is a block diagram of the connector 135a. The connector 135a includes a plug 1351 connected to an end of the branch line 131a and a socket 1352 connected to an end of the output line 131b connected to a +terminal of the solar cell module 111. The overcurrent protecting device 134 is connected between the plug 1351 and the socket 1352. The overcurrent protecting device 134 includes a socket 1341 which can be easily inserted into and pulled out of the plug 1351 at one end, and includes a plug 1342 that can be easily inserted into and pulled out of the socket 1352 at the other end.

An overcurrent protecting element 134a is arranged between the plug 1341 and the socket 1342. The plug 1341, the socket 1342, and the overcurrent protecting element 134a are desirably integrated with each other to make a replacing operation easy. The plug 1351 and the socket 1352 may have shapes that are not fitted to each other not to be connected to each other without being sandwich the overcurrent protecting device 134. In this case, in a connecting operation between the solar cell string and the branch cable or a replacing operation of the overcurrent protecting elements 134a, the plug 1351 and the socket 1352 are not erroneously connected to each other, and a burden in the operation is reduced.

In this case, the overcurrent protecting element 134a is a fuse that is partially fused in connection when a rated current or more flows in the solar cell module 111 or the branch lines 131. The fuse is stored in transparent glass. A temperature-sensitive agent or a color fixing agent may be sealed in the glass. Thermo Paint, Thermo Proof, and Thermo Label available from NICHIYU GIKEN KOGYO CO., LTD are known as temperature-sensitive agents on the market. In particular, as a temperature-sensitive agent, an agent that changes in color by a temperature of an element in fusing of a fuse or a temperature of a fuse outer package is preferably used. As both the temperature-sensitive agent and the color fixing agent, an arc-extinguishing material may be sealed. Alternatively, heat-sensitive paper is arranged in the transparent glass such that the heat-sensitive paper can be seen from the output. The temperature-sensitive agent, the color fixing agent, and the heat-sensitive paper change colors or fix colors by heat in heat generation by the fusing of the fuse to indicate that the fuse is fused.

FIG. 5 is another block diagram of the overcurrent protecting device 134. In FIG. 5, unlike in FIG. 4, the plug 1341, the socket 1342, and the overcurrent protecting element 134a are not integrated with each other, the plug 1341 and the overcurrent protecting element 134a are connected by a connection line 1343, and the socket 1342 and the overcurrent protecting element 134a are connected by a connection line 1344. The other configurations in FIG. 5 are the same as those in FIG. 4.

In this case, the degree of freedom of arrangements of the plug 1341 and the socket 1342 can be obtained in accordance with the shapes of the trunk lines 101 and 102 arranged on a rear side of a solar cell base or the like that fixes a solar cell string to make it possible arrange the overcurrent protecting element 134a on a rear surface side of the solar cell string at an almost eye level of an examiner who observes the solar power generation system.

FIG. 6 shows an internal configuration of the branch connection unit 141. FIG. 6(a) is an internal perspective view of the branch connection unit 141, FIG. 6(b) is an internal plan view of the branch connection unit 141, FIG. 6(c) is a cross-sectional view taken along an A-A′ line, and FIG. 6(d) is a circuit diagram of the branch connection unit 141.

As shown in FIG. 6(a), the branch connection unit 141 includes trunk lines 101a and 101b, the blocking diode 141a, the large heat sink 141b, the small heat sink 141c, and the branch line 131a. One trunk line 101a is connected to one end of the large heat sink 141b, and the other trunk line 101b is connected to the other end of the large heat sink 141b. The large heat sink 141b also serves as a terminal base, and is connected to one terminal of the blocking diode 141a. The other terminal of the blocking diode 141 a is connected to the small heat sink 141c also serving as a terminal base, and the branch line 131a is connected to the small heat sink 141c. The large heat sink 141b and the small heat sink 141c are positioned having a satisfactory space 141e (1.5 mm in this embodiment) complied with a withstand voltage required by the system, so as to prevent short circuit of them.

FIG. 6(b) shows an internal plan view of the branch connection unit 141. The large heat sink 141b is positioned between the trunk lines 101a and 101b, one end of the large heat sink 141b is coupled to the trunk line 101a at the side next to the junction box, and the other end is coupled to the trunk line 101b at a distal side. As an electric circuit, the trunk lines 101a and 101b may be coupled to any portions of the large heat sink 141b. However, from the point of view of dissipating heat, it is preferable that the trunk lines 101a and 101b be positioned next to the heat generation portion of the blocking diode 141a so that the heat generated from the blocking diode 141a is dissipated to the trunk lines 101a and 101b. That is, whereas during the power generation operation, a current preferably flows through the blocking diode 141a and the trunk lines 1011a and 101b to generate heat, the heat temperature generated from the blocking diode 141a is higher so that the heat from the blocking diode 141 conducts through the trunk lines 101a and 101b via the large heat sink 141b as shown by arrows in FIG. 6 (b). The trunk lines 101a and 101b are very long and are made of thick wires enough to flow the generated current, thereby providing a high heat dissipation effect.

Though the blocking diode 141a is positioned within the branch connection unit 141 between the trunk line 101 and the branch line 131a in FIG. 6, the blocking diode 141a may be stored in the connector 135a connected to the branch line 131a connected to the trunk line 101a and the module 111. Even though the blocking diode 141a is arranged in the connector 135a, the blocking diode 141a need only be thermally combined with the large heat sink 141b.

The large heat sink 141b may also serve as a terminal base to connect one of the connection terminals of the blocking diode 141 a to the trunk line.

The large heat sink 141b is a heat sink integrated with the package of the blocking diode 141a, and the heat sink and the trunk line may be thermally combined with each other.

FIG. 6 (c) illustrates a cross- sectional view taken on line A-A′ of FIG. 6(a) and shows a structure in which the large heat sink 141b and the small heat sink 141c are positioned on a bottom surface of a container 141h of the blocking diode 141a. The blocking diode 141a is attached on the large heat sink 141b. A built-in heat sink 141h is provided with the blocking diode 141a so that the built-in heat sink 141h of the blocking diode 141a is pressed so as to contact with the large heat sink 141b in a surface contact and be thermally combined therewith. Preferably, an adhesive resin with good thermal conductivity is interposed between the built-in heat sink 141h and the large heat sink 141b. For example, an epoxy resin, silicone grease or thermal conductive silicone resin with thermal conductivity may be suitable. One terminal 141f of the blocking diode 141a is coupled to the trunk lines 101a and 101b through the large heat sink 141b. The other terminal 141g of the blocking diode 141a is connected to the branch line 131a through the small heat sink 141c.

As shown by the arrows in FIG. 6 (c), the heat generated from the blocking diode 141a is dissipated by the built-in heat sink 141h and the large heat sink 141b and drifted to the trunk lines 101a and 101b to be further dissipated by them. Since, according to the construction of the present invention, the heat is dissipated by the trunk lines 101a and 101b, the area of the built-in heat sink 141h and the large heat sink 141b can be minimized. Although the large heat sink 141b is used in FIG. 6, when the built-in heat sink 141h is provided with the blocking diode 141a, it is possible that the heat from the built-in heat sink 141h is drifted to the trunk lines 101a and 101b for dissipating the heat by thermally combining the trunk lines 101a and 101b with the built-in heat sink 141h.

As shown in FIG. 6(d), the electric circuit of the blocking diode 141 a is such that one terminal 141 f of the blocking diode 141 a is coupled to the trunk lines 101a and 101b and the other terminal 141g thereof is coupled to the branch line 131a.

The blocking diode 141a is stored in a box made of PPS (Polyphenylene Sulfide) with high resistance to heat and a lid made of PPE (Polyphenylene ether) with high flexibility, namely, a product of PPO (Poliophenylene oxide) (registered trademark). These resin materials are only examples, and any other resin can be used. Further, it may be possible that the box and the lid are made of the same resin. In such a case, when PPS is used, it is preferable to be highly resistant to atmosphere change. When a box made of PPS is used, the large heat sink 141b and the small heat sink 141c are positioned on the base of the box made of PPS, so that the blocking diode 141a is positioned on the large heat sink 141b. Hence, one terminal 141f of the blocking diode 141a is in contact with the large heat sink 141b, and the other terminal 141g of the blocking diode 141a is in contact with the small heat sink 141c, while the trunk lines 101a and 101b are in contact with the large heat sink 141b, and the branch line 131a is in contact with the small heat sink 141c, so that solder pastes are affixed on the respective contact portions and they pass through a reflow furnace to solder the contact portions. In passing through the reflow furnace, only the respective contact portions are preferably heated without heating the trunk lines 101a and 101b and the branch line 131a. Other than using the reflow furnace for soldering, a manual soldering operation may be used. As described next, electrical connection may be performed by filling a resin to push the respective contact portions.

After the respective contact portions are thus soldered, a curing resin is potted within the box. As the curing resin, silicone and epoxy resin are used, but any other resin such as an addition type, a heat type, a UV curing type and a condensation type can be used. However, the two-part addition type of resin is most preferable since it can be cured regardless of the moisture. When the condensation type of resin is used, a two-part condensation type of resin is preferable since it is hardly dependent upon the moisture. Since an one-part condensation type of resin absorbs the moisture from the atmosphere, the control of a curing speed is difficult because the silicone may be chapped depending upon the curing conditions to cause insulation fault. Since, especially, the power lines for the solar power generation system of the present invention are used outside the house in which it is assumed that water may pool around the power lines or the power lines may be soaked within a pool, the one-part condensation type of resin may cause insulation fault. The heat type of resin must be further heated after the resin has been filled. The box made of PPS and the lid made of PPO should have heat resistance as well as a blocking diode 141a. In addition, the solder portions should not fall off. The UV curing type of resin requires radiation of ultra violet rays.

As a resin for potting inside the box of the blocking diode according to the present invention, the specific examples listed below are suitable. As the one-part condensation type of resin, KE-4890 (product name), KE-4896 (product name) each of Sin-Etsu Chemical Co., Ltd., TSE-399 (product name), TSE-392 (product name) each of Momentive Performance Materials Worldwide Inc. and SE-9185 (product name), SE-9188 (product name) each of Dow Corning Toray Co., Ltd. are listed. As the two-part condensation type of resin, KE-200 (product name) of Sin-Etsu Chemical Co., Ltd. is listed. As the addition type of resin, KE1204 (product name) of Sin-Etsu Chemical Co., Ltd. and EE1840, Sylgard 184 (product name) each of Dow Corning Toray Co., Ltd. are listed.

As mentioned above, by filling the potting resin, the thermal conductivity of the potting resin is larger than the atmosphere to become possible to expect the heat dissipation effect.

The blocking diode 141a is stored within a container formed by the box made of PPS and the lid made of PPO, while the trunk lines 101a and 101b are introduced into the inside of the container through a hole created in the box made of PPO. When the trunk line 101a or 101b is introduced through the hole, the trunk line 101a or 101b is pushed into the hole, and the surfaces of the hole and the trunk line 101a or 101b are coated and adhered with an adhesive. Further, since according to the present invention, the potting agent is potted into the container, after the trunk line 101a or 101b is brought into contact with and coupled to the large heat sink 141b, the trunk line 101a or 101b is fixed by the potting agent. By thus potting, the trunk line 101a or 101b is pushed into and fixed in the hole by the adhesive between the hole and the trunk line 101a or 10ab and further fixed by the potting agent.

As described above, the branch connection unit 141 includes the blocking diode 141a within the inside thereof. However, since the branch connection unit 142 does not include a blocking diode, the branch lines 131 are branched from a trunk line 102, and a detailed description thereof will be omitted.

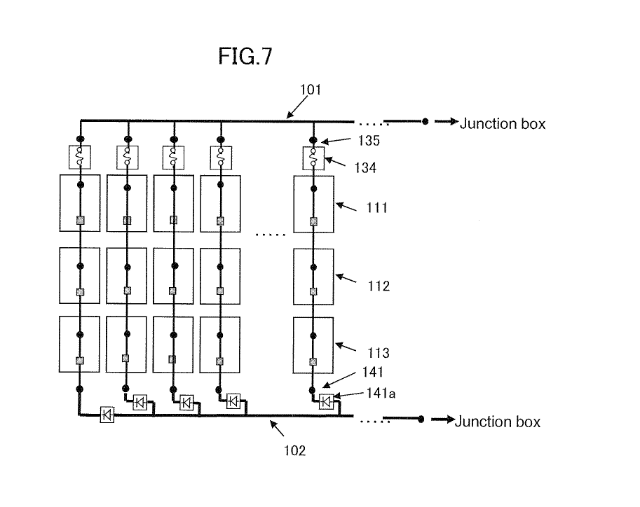

FIG. 3 shows a case in which the blocking diode 141a is stored in the branch connection unit 141 of the trunk line 101 and coupled. The trunk line 101 is high-voltage side wiring of the solar cell module 111. On the contrary, as shown in FIG. 7, the blocking diode 141a may be positioned in a branch connection unit 142 of a trunk line 102. The trunk line 102 is low-voltage side wiring of the solar cell module 111. Here, the high-voltage side wiring means plus-electrode side wiring of the solar cell module 111. Further, the low-voltage side wiring means minus-electrode side wiring of the solar cell module 111. In the case where the blocking diode 141a is thus positioned at the branch connection unit 142 of the low-voltage side wiring, an earth fault examination of the solar cell module 111 can be easily made. That is, when a plurality of solar cell modules are interconnected across the trunk lines 101 and 102 and one of the modules causes earth fault, an electric current is supplied from the junction box 122 so that the electric current flows through the solar cell module causing the earth fault, because the blocking diode 141a is not connected between the junction box 122 and the solar cell module causing the earth fault. Detecting this electric current enables the solar cell module causing the earth fault to be detected.

When one of the solar cell modules interconnected across the trunk lines 101 and 102 causes earth fault, and when an overcurrent flows in the overcurrent protecting element 134a to disconnect the overcurrent protecting element 134a, the overcurrent protecting element 134a of the solar cell string connected to the trunk line to be inspected can be rapidly specified by an examiner. In cooperation with the detection of earth fault, maintenance and management of the solar power generation system are satisfied.

When the connection is performed as shown in FIG. 7, fault in the blocking diode 141a is detected as follows.

More specifically, while the solar cells do not generate power such as at night, a voltage is applied to the trunk lines for examination. The voltage is applied such that the high-voltage side wiring, i.e., the trunk line 101 is positive and the low-voltage side wiring, i.e., the trunk line 102 is negative. Since this voltage direction is reverse to the direction of the blocking diode 141a, the normal conditions of all the blocking diodes 141a prevent any electric current from flowing. If at least one of the blocking diodes is at fault in a short-circuit mode, an electric current can flow so that a solar cell string connected to the diode at fault generates heat. It is observed by a thermograph so that it is easily possible to identify a solar cell string at fault even when a great number of solar cell modules are provided in a large-scale power generation system.

FIGS. 3, 6, and 7 show a case in which the blocking diode 141a is stored in the branch connection unit 141 and the overcurrent protecting device 134 is connected to the connector 135. However, the overcurrent protecting device 134 may be stored in the branch connection unit 141 together with the blocking diode 141a, or may be stored in the connector 135 together with the blocking diode 141a.

The overcurrent protecting device 134 need only be connected to the connector 135 without storing the blocking diode 141a in the branch connection unit 141. The blocking diode is to prevent a generated current from reversely flowing in a solar cell panel having a small generated energy when the generated energies of the solar cell panels are not even. However, when the overcurrent protecting device 134 is connected without connecting a blocking diode, when all the solar cell panels generate power, a generated power flows from another solar cell panel into a solar cell panel having a small generated energy, and a reverse current flows to disconnect the overcurrent protecting device. In this manner, the solar cell panel having a small generated energy is disconnected from the solar power generation system.

In a combination between the blocking diode and the overcurrent protecting device, when the blocking diode fails in a short-circuit mode, as in the case the overcurrent protecting device 134 is connected without connecting the blocking diode described above, if a generated voltage of the solar cell string to which the blocking diode failing in the short-circuit mode is connected is low, a reverse current flows to disconnect the overcurrent protecting device. More specifically, in this case, the state of the overcurrent protecting device can be checked, and a solar cell string in failure can be specified as fast as possible. When an abnormality occurs, it is checked whether a blocking diode fails or a solar cell module fails, and the blocking diode or the solar cell module can be quickly arbitrarily replaced in replacement of the overcurrent protecting device.

In a combination between the blocking diode and the overcurrent protecting device interconnected in series, the blocking diode and the overcurrent protecting device may be integrally stored in a connector connected between the branch line and the output line such that the blocking diode and the overcurrent protecting device can be replaced at once.

In a solar cell string in which a plurality of solar cell modules are interconnected in series, an overcurrent protecting device or a blocking diode may be connected between the solar cell modules in the solar cell string. In this case, on a rear surface side of the solar cell string, the overcurrent protecting element 134a can be arranged at an almost eye level of an examiner who monitors the solar power generation system.

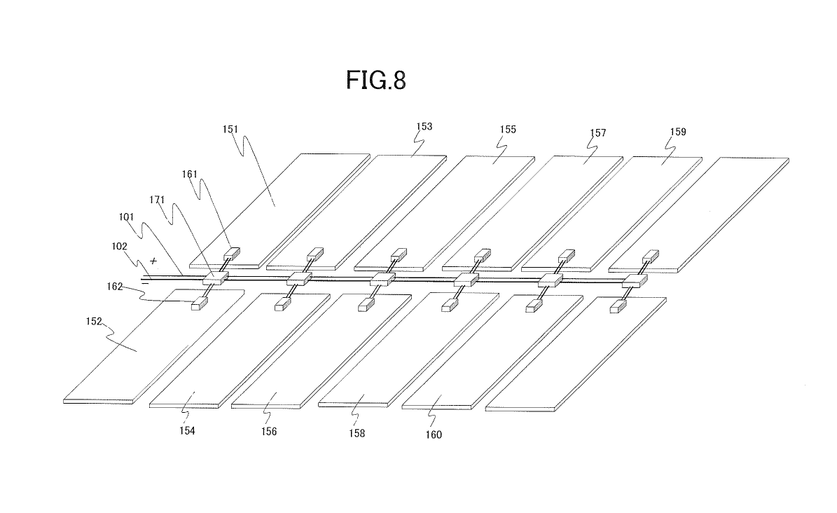

The solar power generation system described above, as shown in FIGS. 1, 3, and 7, shows a configuration in which the plurality of solar cell strings 121 each obtained by interconnecting the three solar cell modules 111, 112, and 113 in series between the trunk line 101 and the trunk line 102 are arranged. On the contrary, according to the examples as shown in FIGS. 8 to 13, the two trunk lines 101 and 102 are positioned to be collectively integrated. The two trunk lines 101 and 102 may be integrated by using a two-line wire formed as a pair of wires, or may be integrated by closely positioning the two trunk lines 101 and 102.

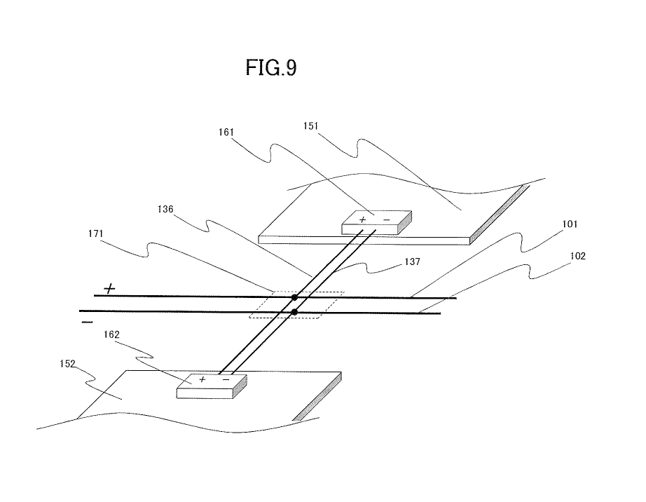

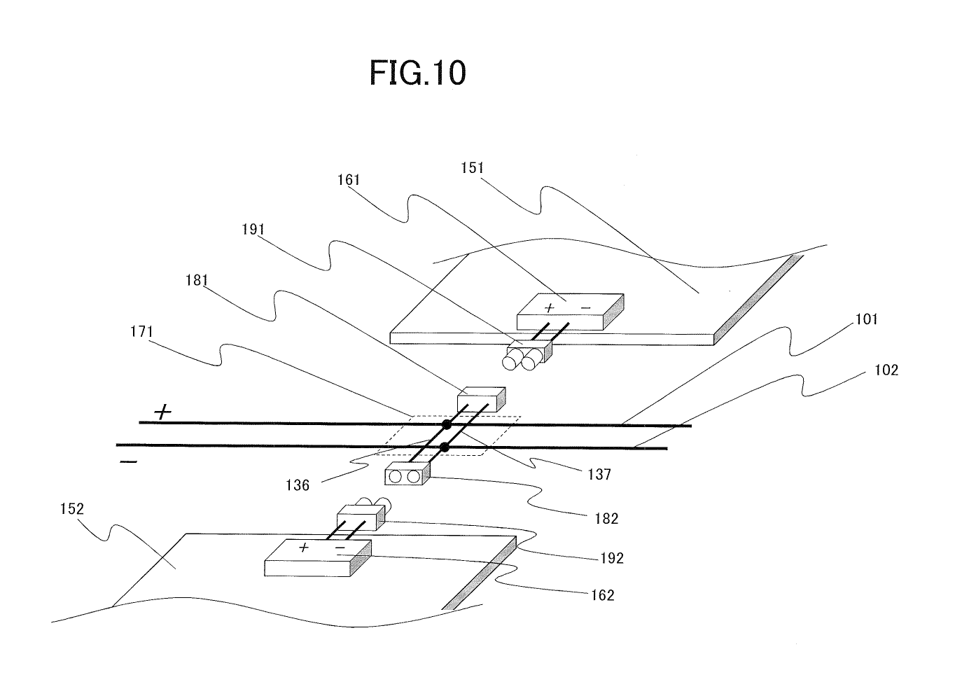

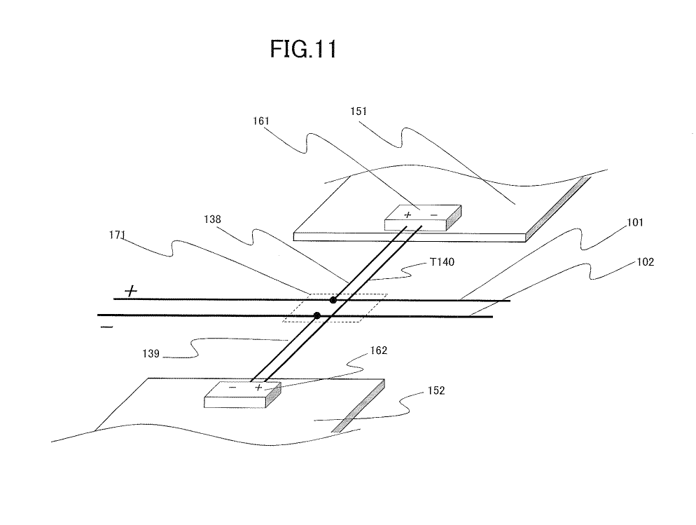

FIG. 8 shows a schematic diagram illustrating two examples as described below. FIGS. 9 and 10 show a first example and FIGS. 11 to 13 show a second example. According to these examples, the trunk lines 101 and 102 are arranged between two solar cell panels 151 and 152, between solar cell panels 153 and 154, . . . in each of which a solar cell string obtained by interconnecting a plurality of solar cell modules in series is paneled by a stainless frame, surface-protecting glass, and a rear-surface reinforcing plate. A terminal box 171 of each of the solar cell panels 151, 152, and 153, 154, . . . is positioned at the position close to the trunk lines 101 and 102, so that the length of a wire for connecting the solar cell panels 151 and 152 to the trunk lines 101 and 102 can be minimized. In addition, since the two-line connectors can be easily adopted, the length of the connection wire can be minimized to perform parallel connection, as compared to the case where the wires are extended to a connection box 122 per each solar cell panel.

As shown in FIG. 8, according to the first and second examples, the high-voltage side wiring 101 and the low-voltage side wiring 102 are collectively integrated and positioned. A connection unit 171 is arranged at a position where the solar cell panels 151 and 152 are arranged, and the solar cell panels 151 and 152 are arranged on both the sides of the trunk lines 101 and 102. Branch connection units 161 and 162 of the solar cell panels 151 and 152 are connected by branch lines to interconnect the solar cell panels 151 and 152 in parallel.

As a preferable arrangement of the solar power generation system, a line of solar cell panels are aligned along the trunk lines so that the branch connection units 161 and 162 of the solar cell panels are positioned at the side close to the trunk lines 101 and 102 to shorten the branch lines for wiring from the terminal boxes of the solar cell panels to the trunk lines 101 and 102. In this manner, the length of the branch lines can be made equal to or smaller than the length of the short side of the solar cell panels 101 and 102, a voltage reduction caused by a resistor component of the branch lines can be reduced, an arranging operation of the solar cell panels can be improved, and a wiring material can be advantageously saved.

For another example of arranging the solar power generation system, each line of solar cell panels are aligned at both sides of the trunk lines so that the terminal boxes of both ends of the solar cell panels are positioned as confronting to each other at the side close to the trunk lines. According to the arrangements, the distance from the terminal box of the solar cell panel to the trunk lines can be shortened. As a result, the branch lines can be shortened, a voltage reduction caused by a resistor component of the branch lines can be reduced, an arranging operation of the solar cell panels can be improved, and a wiring material can be advantageously saved.

FIG. 9 shows details of a first example, and is an explanatory diagram of connections between the trunk lines 101 and 102, the connection unit 171, the branch connection units 161 and 162 of the solar cell panels 151 and 152. As shown in FIG. 9, the connection unit 17 is positioned in the middle of the trunk lines 101 and 102, and the branch connection units 161 and 162 of the solar cell panels 151 and 152 are connected to the connection unit 17.

FIG. 10 is a more detailed explanatory diagram of the connection unit 171 and the branch connection units 161 and 162. As shown in FIG. 10, a branch line 136 coupled to a first trunk side connector 181 and a second trunk side connector 182 from the high-voltage side trunk line 101 is coupled to the connection unit 171. A branch line 137 coupled to the first trunk side connector 181 and the second trunk side connector 182 from the low-voltage side trunk line 102 is coupled to the connection unit 171. The first trunk side connector 181 and the second trunk side connector 182 are positioned at both sides of the trunk lines 101 and 102 across them as shown in FIG. 10. A module side connector 191 detachable to the first trunk side connector 181 is positioned as opposed to the first trunk side connector 181. Similarly, a module side connector 192 detachable to the second trunk side connector 182 is positioned as opposed to the second trunk side connector 182.

The module side connector 191 is connected to the branch connection unit 161 of the solar cell panel 151, and the module side connector 192 is connected to the branch connection unit 162 of the solar cell panel 152.

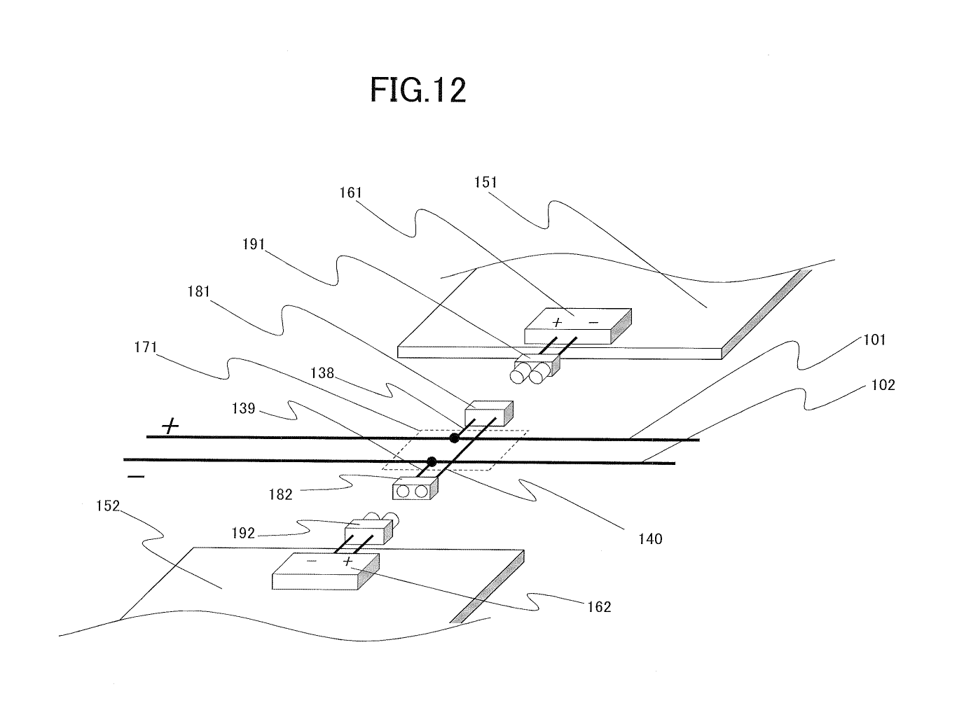

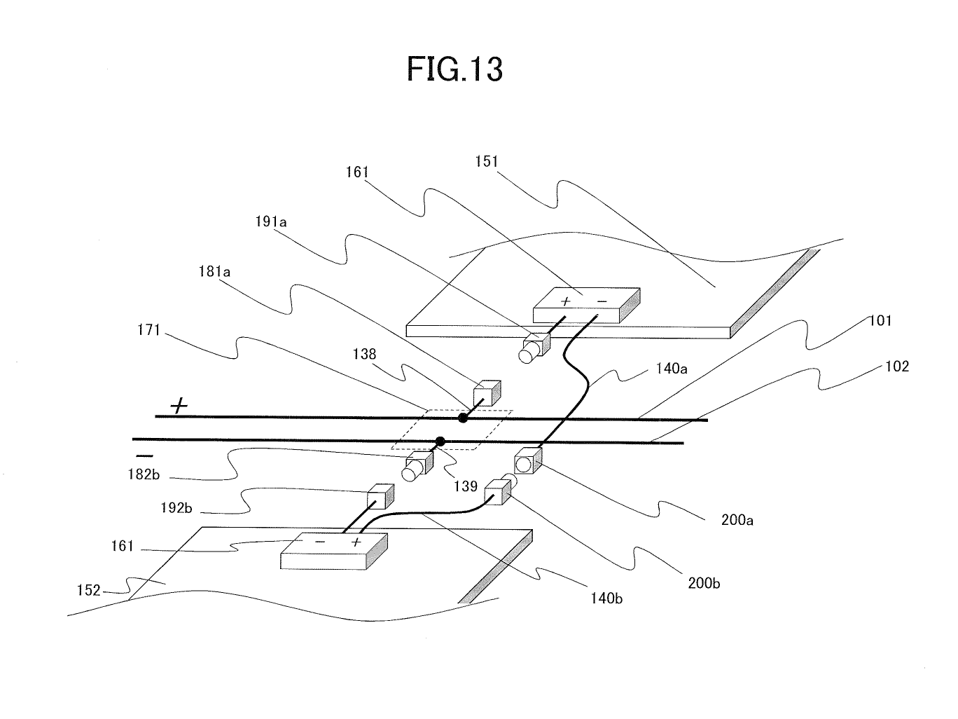

FIGS. 11 and 12 show details of a second example, and FIG. 13 shows a modification of the second example.

As shown in FIG. 11, in the second example, the two solar cell panels 151 and 152 respectively positioned at both sides of the trunk lines 101 and 102 are interconnected in series. Namely, a branch line 138 coupled to the high-voltage side trunk line 101 from the connection unit 171 of the trunk lines 101 and 102 is connected to a plus electrode of the branch connection unit 161 of the solar cell panel 151. A branch line 139 coupled to the low-voltage side trunk line 102 is connected to a minus electrode of the branch connection unit 162 of the solar cell panel 152. Furthermore, a minus electrode of the branch connection unit 161 of the solar cell panel 151 and a plus electrode of a branch connection unit F162 of the solar cell panel 152 are connected to each other by a branch line 140.

FIG. 12 is a detailed explanatory diagram of the connection unit 171 and the branch connection units 161 and 162. As shown in FIG. 12, to the connection unit 171, a connection from the high-voltage side trunk line 101 to the first trunk side connector 181 is made by a branch line 138. Similarly, to the connection unit 171, a connection from the low-voltage side trunk line 102 to the second trunk side connector 182 is made by a branch line 139. The first trunk side connector 181 and the second trunk side connector 182 are connected to each other by the branch line 140.

The module side connector 191 detachable to the first trunk side connector 181 is positioned as opposed to the first trunk side connector 181. Similarly, the module side connector 192 detachable to the second trunk side connector 182 is positioned as opposed to the second trunk side connector 182. The module side connector 191 is connected to a branch connection unit F161 of the solar cell panel 151, and the module side connector 192 is connected to the branch connection unit 162 of the solar cell panel 152. The branch connection units 161 and 162 each include the blocking diode 142a as described in FIG. 6. Therefore, the module side connector 191 is inserted into the first trunk side connector 181 and the module side connector 192 is inserted into the second trunk side connector 182 so that the two solar cell panels 151 and 152 are interconnected in series and coupled across the high-voltage side trunk line 101 and the low-voltage side trunk line 102.

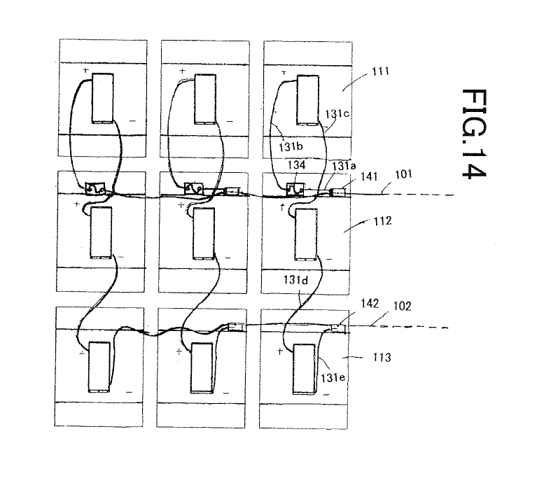

FIG. 13 shows a modification of the second example shown in FIG. 12. As shown in FIG. 13, the branch line 140 for connecting the solar cell panels 151 and 152 is featured to be divided into branch lines 140a and 140b the tips of which are connected to connectors 200a and 200b, respectively. The connector 181 is a single-line connector including only the branch line 138, and the connector 182 is a single-line connector including only the branch line 139. As a result, as shown in FIG. 13, connectors 181a and 182a can be made smaller than the connectors 181 and 182 in FIG. 12. In this manner, since the branch line 140 for connecting the solar cell panels 151 and 152 is divided into branch lines 140a and 140b, the branch lines can be freely wired such that branch lines 140a and 140b are connected through the outside of the solar cell panels 151 and 152. For example, as shown in FIG. 14, two solar cell panels P1 and P2 can be interconnected in series.

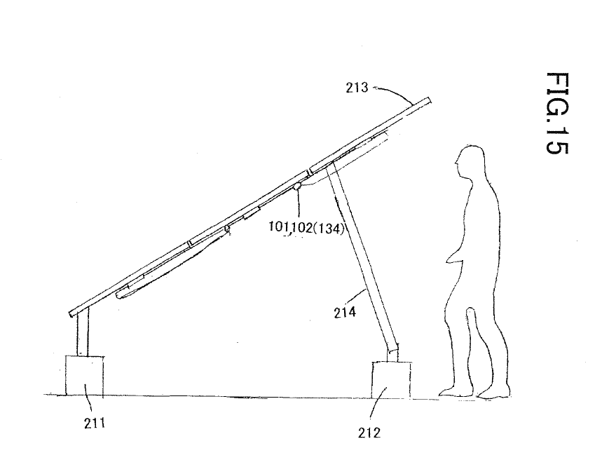

A solar cell panel P is installed as shown in FIG. 15. In FIG. 15, a solar cell base 213 obtained by mounting solar cell panels on bases 211 and 212 and a support post 214 are installed. In this case, the trunk lines 101 and 102 are arranged on a rear surface side of the solar cell base 213 at an almost eye level of an examiner who monitors the solar power generation system. When the examiner monitors while riding on a vehicle, the solar cell base is arranged at an eye level of the examiner who rides on the vehicle. Furthermore, the solar cell base is installed such that the overcurrent protecting devices 134 are positioned on the trunk lines 101 and 102 near the eye level position.

Therefore, the examiner can monitor overcurrent protecting devices 134 in the daytime in which the solar cells generate electricity and in other times and at any time, disconnection of the overcurrent protecting device 134 can be easily detected.

A solar cell panel in which disconnection of the overcurrent protecting device 134 frequently occurs may be caused by the following reasons. As the first reason, generated energy of one certain solar cell panel is smaller than that of another solar cell panel. For this reason, an electric power generated by the other solar cell panel goes around to the solar cell panel the electric power of which decreases. As the second reason, a rated value of one certain solar cell panel is smaller than a rated value of another solar cell panel. For this reason, an electric power generated by the other solar cell panel goes around to the solar cell panel the rated value of which is smaller than that of the other solar cell panel.

Since a generated output of the solar cell panel in which disconnection of the overcurrent protecting device 134 frequently occurs is reduced, the solar cell panel is replaced with a rated-output solar cell panel to make it possible to prevent a total generated output of the solar power generation system from being reduced.

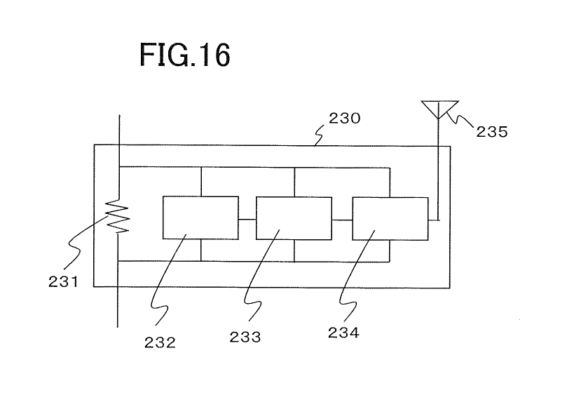

FIG. 16 shows an abnormality detecting unit 230 that detects abnormality in the solar cell panel and the overcurrent protecting device in the solar power generation system according to the present invention. As shown in FIG. 16, the abnormality detecting unit 230 is interconnected to the solar cell string in series and operated by an output power from the solar cell string. More specifically, when a solar cell generates electricity, a part of a solar cell output is extracted by a resistor 231 connected to the solar cell string in series. By using the output as a power supply, a signal circuit 232, an oscillation circuit 233, and a transmission circuit 234 are operated, and a radio wave is transmitted from an antenna 235. Alternatively, in place of the antenna 235, a signal is transmitted from a power line carrier communication apparatus. The signal circuit 232 generates inherent data such as an address and an installation place of a solar cell string to which, for example, the abnormality detecting unit 230 is attached. The oscillation circuit 233 generates a high-frequency signal to transmit a radio wave. In order to receive a radio wave from the antenna 235 or receive a signal using a power line, the transmission circuit 234 is desirably controlled such that they periodically operate for about several hours.

Thus, when a solar cell normally operates, by an electric power generated by the solar cell, the abnormality detecting unit 230 transmits the radio wave or the signal to the receiving unit. However, when the solar cell does not generate electricity, the abnormality detecting circuit 230 does not transmit a radio wave. In this manner, an observation post of the solar power generation system determines that the solar power generation system is normal when the abnormality detecting circuit 230 transmits a radio wave, and determines that the solar power generation system is abnormal when no radio wave is transmitted.

A solar cell module will be described below.

First, the solar cell strings for outputting the high power will be described.

An output voltage Vdc of each high-power solar cell string is set to be approximately 12 times to several 10 times the AC output voltage (effective value) of a DC/AC converter IN. Therefore, the output voltage Vdc of a solar cell string S is 140 V to 1000 V, when the AC output voltage is 100 V.

When the output voltage Vdc of the solar cell string S is set to a high voltage of 600 V to 1000 V, a power line cable input to a power converter can be shortened.

When electric energy input to the power converter is considered to be constant, the higher an input voltage to the power converter is, the smaller an amount of electric current can be set to be, and the smaller the thickness of the power line cable can be made. Alternatively, since a potential difference applied to an overcurrent protecting device at a branch portion can be a high voltage, the countermeasure of the present invention needs to be taken.

With this configuration, direct input to the DC/AC converter IN is possible, and an AC high-voltage-output solar power generation system can be realized. Furthermore, since any number of solar cell strings can be connected in parallel, the present invention can be applied to small scale power generating systems to large scale power generating systems. Moreover, it is ideal that all the output voltages of the solar cell strings are equal, and in that case, it is possible to take out the maximum power; however, in the present invention, the solar cell strings are connected in parallel, and therefore it is possible to take out power effectively even if all the solar cell strings do not output an equal output voltage.

The solar cell modules configuring the above-described solar cell string include a plurality of thin-film solar cell elements interconnected in series, each of the thin-film solar cell elements including a surface electrode, a photoelectric conversion layer, and a back surface electrode laminated in this order. The above described photovoltaic power system requiring a high voltage as much as several hundreds V and the photovoltaic power system for general residence use or the like that links with commercial power can be achieved by using a thin-film solar cell module that is configured as follows.

<First thin-film solar cell module>-Example of 53 stages×12 parallels ×2 blocks in series-

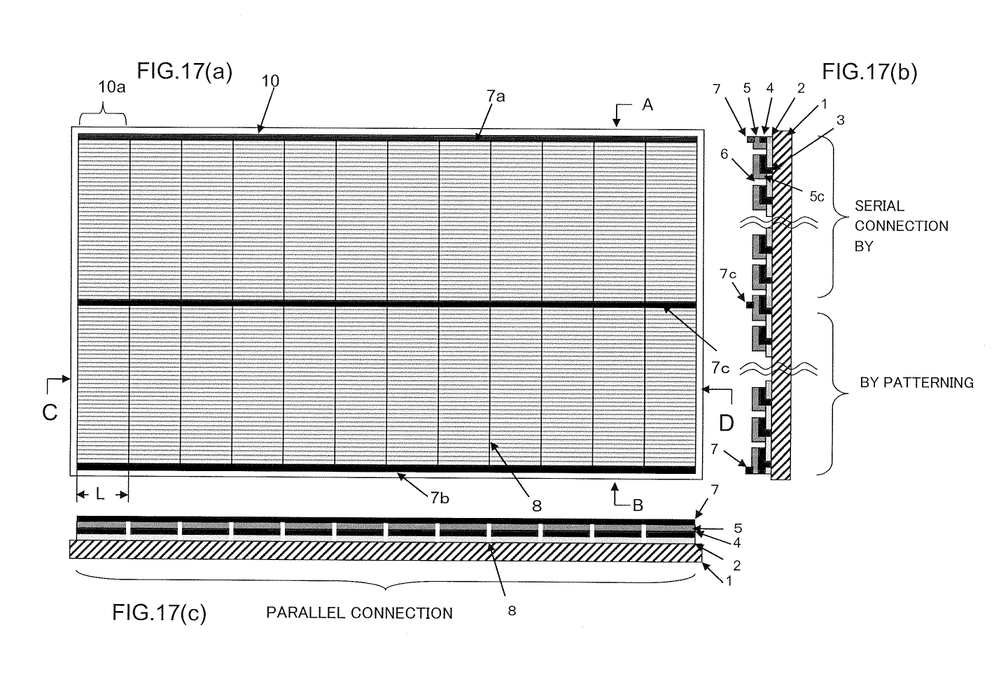

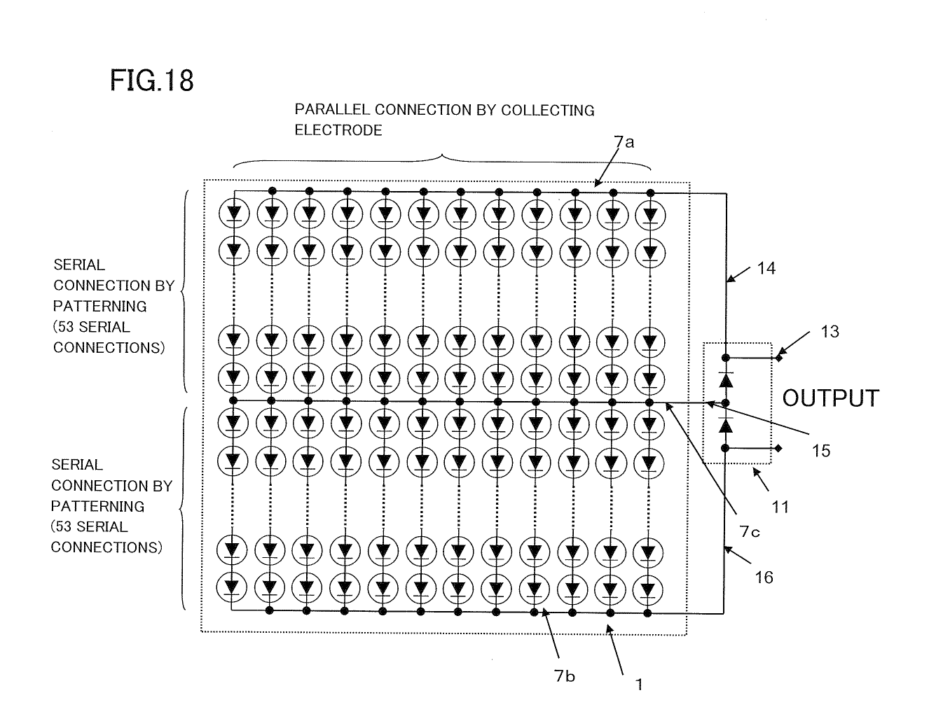

FIG. 17 illustrates an integrated thin-film solar cell module associated with the first thin-film solar cell module, and FIG. 17 (a) is a plan view, FIG. 17 (b) is a cross-sectional view taken along lines A-B of FIG. 17 (a), and FIG. 17 (c) is a cross-sectional view taken along lines C-D of FIG. 17 (a). FIG. 18 illustrates a circuit diagram.

In the first thin-film solar cell module, a supporting substrate 1 is, for example, a translucent glass substrate or a resin substrate such as a polyimide. On the substrate (surface), a first electrode (for example, a transparent conductive film of SnO₂ (tin oxide)) is formed by a thermal CVD method or the like. As long as the first electrode is a transparent electrode, it may be, for example, ITO which is a mixture of SnO₂ and In2₂O₃. Thereafter, the transparent conductive film is appropriately removed by patterning to form dividing scribe lines 3. Formation of the dividing scribe lines 3 forms a first electrode 2 that is divided into several pieces. The dividing scribe lines 3 are formed by cutting the first electrode by a groove-like shape (scribe line shape) by means of a laser scribing beam, for example.

Next, on the first electrode 2, a photoelectric conversion layer 4 is formed by forming a film of semiconductor layers (for example, amorphous silicon or microcrystalline silicon) of, for example, p-type, i-type, and n-type in sequence by a CVD method. At the same time, the dividing scribe lines 3 are also filled with the photoelectric conversion layer. The photoelectric conversion layer 4 may be of a p-n junction or a p-i-n junction. In addition, the photoelectric conversion layer 4 may be laminated into one, two, three, or more stages, and sensitivity of each solar cell element may be made to sequentially shift to a longer wavelength as it is distant from the substrate side. When the photoelectric conversion layer is laminated into a plurality of layers as described above, the layers may include a layer such as a contact layer and an intermediate reflection layer therebetween.

When the photoelectric conversion layer 4 is laminated into a plurality of layers, all the semiconductor layers may be an amorphous semiconductor or a microcrystalline semiconductor, or may be any combination of an amorphous semiconductor and a microcrystalline semiconductor. That is, the structure may be a laminate in which the first photoelectric conversion layer is of an amorphous semiconductor and the second and third photoelectric conversion layers are of a microcrystalline semiconductor; a laminate in which the first and second photoelectric conversion layers are of an amorphous semiconductor and the third photoelectric conversion layer is of a microcrystalline semiconductor; or a laminate in which the first photoelectric conversion layer is of a microcrystalline semiconductor and the second and third photoelectric conversion layers are of an amorphous semiconductor.

In addition, while the above-described photoelectric conversion layer 4 is of a p-n junction or a p-i-n junction, it may be of an n-p junction or an n-i-p junction. Furthermore, a junction part between the p-type semiconductor layer and the i-type semiconductor layer may or may not have a buffer layer of an i-type amorphous material. Usually, in the p-type semiconductor layer, a p-type impurity atom such as boron and aluminum is doped, and in the n-type semiconductor layer, an n-type impurity atom such as phosphorus is doped. The i-type semiconductor layer may be completely undoped or may be of a weak p-type or a weak n-type including a small amount of impurity.

The photoelectric conversion layer 4 is not limited to silicon, and may be formed of a silicon semiconductor such as silicon carbide containing carbon or silicon germanium containing germanium, or a compound semiconductor of a compound such as Cu(InGa)Se₂, CdTe, and CuInSe₂. In addition to the crystalline or amorphous semiconductor that is used as described above, a dye sensitizing material can also be used.

Here, each photoelectric conversion layer 4 of the thin-film solar cell module as shown in FIG. 11 is of a p-i-n junction, and a crystalline thin-film silicon that photo-electrically converts infrared light and an amorphous thin film silicon that photo-electrically converts visual light are laminated to configure one thin-film cell. With this structure, a two junction type thin-film solar cell obtained by laminating two cells is configured.

Then, connection grooves are formed on the photoelectric conversion layer 4 by laser scribing or the like, and a second electrode (ZnO/Ag electrode or the like) is formed thereon by sputtering or the like. In this manner, the connection grooves are filled with the second electrode material, and contact lines 5c are formed. In this manner, the second electrode 5 divided on the photoelectric conversion layer 4 and the adjacent first electrode 2 on the photoelectric conversion layer 4 will be connected via the contact lines 5c, and a plurality of thin-film solar cell elements will be connected in series. Furthermore, cell dividing grooves 6 are formed in parallel with the contact lines 5c by laser scribing or the like to divide the thin-film solar cell elements to a plurality of pieces. Thereby, in an example of FIG. 17, each individual solar cell element (cell) is divided to be in an equal size, and a thin-film solar cell element 10 (hereinafter, may be referred to as cell string) is formed, having a plurality of solar cell elements connected in series in the vertical direction of FIG. 17.

The dividing scribe lines 3, the contact lines 5c, and the cell dividing grooves 6 are formed such that the stage number n of a connection in-series of the thin-film solar cell element is an integral multiple of the following formula (1). More specifically, the number of stages n of the series connection of the thin-film solar cell elements in the cell string satisfies the following formula (1):

n<Rshm/2.5/Vpm×Ipm+1 (1)

wherein Rshm is the most frequent short-circuit resistance value of the thin-film solar cell elements;

Vpm is an optimum operation voltage of the thin-film solar cell elements; and

Ipm is an optimum operation current of the thin-film solar cell elements.

The thin-film solar cell module of the above-described configuration is in a state where the output of the thin-film solar cell string is short-circuited by a bypass diode, when the thin-film solar cell element including n stages of solar cell elements integrated is in a hotspot state due to one stage of thin-film solar cell elements of those being in shade. An equivalent circuit in this case is in a state where (n−1) stages of thin-film solar cell elements in light have one stage of thin-film solar cell elements not in light connected thereto as a load. Therefore, most power generated in the region being in light in the thin-film solar cell module will be consumed in the thin-film solar cell elements in shade, without being taken out of the thin-film solar cell module. Then, when the reverse breakdown voltage is sufficiently high in the normal region of the thin-film solar cell elements in shade, the current that flows to the thin-film solar cell elements goes to a region within the surface short-circuited by dust, flaws, and protrusions, and a region of low resistance around the laser scribing and the like.

Measures of how easy the current flows include the short-circuit resistance to be worked out from current-voltage characteristics when a backward voltage of approximately 0 to several V is applied to the thin-film solar cell elements. When the short-circuit resistance is Rsh [Ω], the power is most concentrated on the short-circuit part when the short-circuit resistance Rsh is equal to an optimum load Rshpm with respect to the (n−1) stages of cells in light. Therefore, the module needs to be designed so that the short-circuit resistance Rsh is prevented from being close to the value.

For example, an optimum load Rshpm is reached as in the following formula (2), which is the worst, where an optimum operation voltage is Vpm [V] and an optimum operation current is Ipm [A] with respect to one stage of thin-film solar cell elements, and one stage of thin-film solar cell elements are in shade, as described above.

Rshpm=Vpm/Ipm×(n−1) (2)

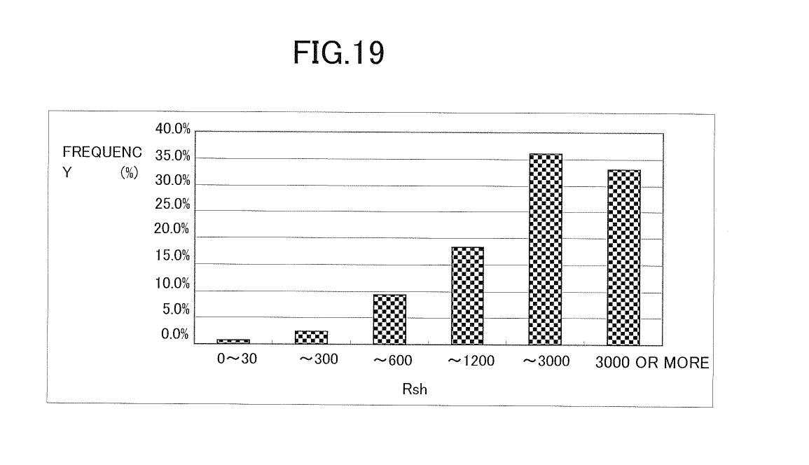

An actual short-circuit resistance Rsh is caused by various causes such as a region within the surface short-circuited by dust, flaws and protrusions, and a region of low resistance around the laser scribing. Rsh varies due to various reasons in a production step, distributed within a certain range. FIG. 19 illustrates the relationship between the varying short-circuit resistance Rsh and power Prsh consumed there according to I-V properties of a representative silicon thin-film solar cell. When the above-described short-circuit resistance Rsh is approximately 2.5 times the optimum load Rshpm, deviating from the optimum load Rshpm, the power Prsh decreases to half or less. That is, in FIG. 19, the power is approximately 8 W when the optimum load Rshpm is approximately 330 Ω, and the power is approximately 4 W when the short-circuit resistance Rsh is 130 Ω. Therefore, it is possible to considerably reduce occurrence of peel-off due to a hotspot, if production can be carried out with the short-circuit resistance Rsh deviated from the optimum load Rshpm by 2.5 times or more. No matter how much the short-circuit load Rsh deviates from the optimum load Rshpm, it is acceptable as long as the deviation is by 2.5 times or more, because the deviation needs only to be by 2.5 times or more.

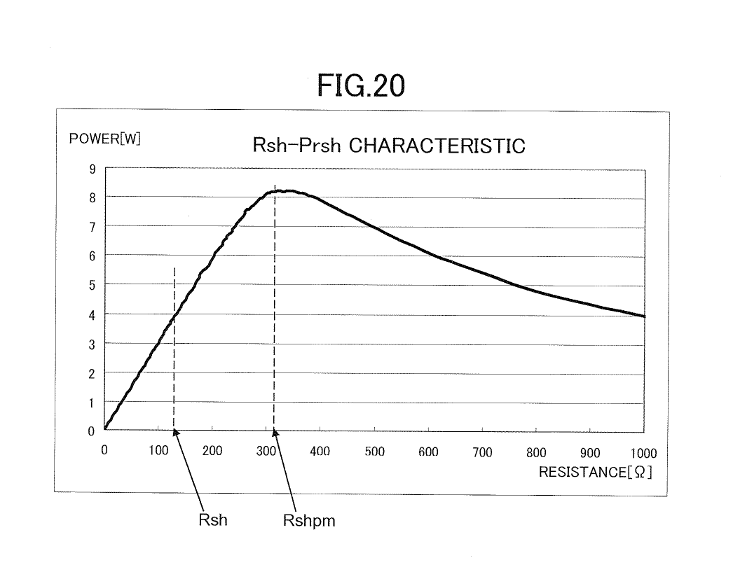

In addition, FIG. 20 illustrates distribution of the short-circuit resistance Rsh of a module actually produced. Factors that impair (=lower) the short-circuit resistance Rsh of the thin-film solar cell elements may include various events such as insufficient division at the dividing scribe lines; short circuit due to dust, protrusions, and pin holes within the surface; increase of reverse leakage current due to variation of production conditions; and lowered resistance of a doped layer. As a main factor around the peak of the distribution of short-circuit resistance Rsh (around 3000 Ω), however, leakage current at the dividing scribe lines mainly causes the lowering of the short-circuit resistance Rsh. In a range of the distribution of the short-circuit resistance Rsh lower than the vicinity of the peak, leakage current within the surface mainly causes the lowering of the short-circuit resistance Rsh.

When the factor of the leakage current is a short circuit within the surface, and a hotspot phenomenon occurs, the short-circuit region within the surface is peeled off or burnt off to cause high resistance. Therefore, F.F. of the cell is improved, offsetting lowering of Isc due to the peel-off. As a result, it is unlikely that the properties deteriorate significantly. However, when the factor of the leakage current is leakage current at the dividing scribe lines, and a hotspot phenomenon occurs, peel-off is generated from the dividing scribe lines. Then, solar cell elements in a normal region are involved to promote the peel-off or affect contact lines nearby. Therefore, in the case of leakage current at the dividing scribe lines, the properties and reliability of the thin-film solar cell module deteriorate significantly compared to the case of leakage current due to the short circuit within the surface.

It is therefore desirable that the above-mentioned optimum load Rshpm comes outside a range where the main factor is leakage current at the dividing scribe lines and stays within a range where the main factor is leakage current within the surface. Specifically, when the most frequent short-circuit resistance value Rsh is Rshm, the optimum load Rshpm needs to be within a range of sufficiently low level with respect to Rshm. Since the short-circuit resistance Prsh for the most frequent value Rshm is approximately half of the short-circuit resistance Prsh for the optimum load Rshpm when the most frequent value Rshm is 2.5 times the optimum load Rshpm, parameters need to be selected so that the following formula (3) is satisfied:

Rshm>2.5×Rshpm=2.5×Vpm÷Ipm×(n−1) (3)

Once type, structure, and production conditions of the solar cell elements constituting the thin-film solar cell module are determined, Vpm, Ipm, and Rshm are almost determined, and then the following formula (1) is obtained by modifying the formula (3). Thereby, the maximum number of integration stages that can keep hotspot resistance is determined.

n<Rshm÷2.5÷Vpm×Ipm+1 (1)

Practically, Rshm>approximately 2000 Ω and Vpm/Ipm=approximately 5 to 10 Ω in reasonable solar cell elements, because too low short-circuit resistance Rsh affects solar cell element properties, though it depends on the form of the solar cell elements. Here, n<80 to 160. In the case of solar cell elements for which the optimum operation voltage Vpm=approximately 1.0 V, any thin-film solar cell modules having an optimum operation voltage of approximately 80 to 160 V will naturally fall within the range.

The problem becomes significant only when the optimum operation voltage of the module is more than approximately 160 V. As a countermeasure for this case, we have found that the problem can be prevented if the number of integration stages is determined so as to meet the formula (1).

In addition, when the maximum number of integration stages is limited in this way and it is desired to obtain a voltage output higher than a voltage output that can be achieved with the number of integration stages as the thin-film solar cell module, the inside of the thin-film solar cell module is divided to a plurality of blocks so that the number of integration stages in each block falls within the range of the formula (1). Furthermore, if each block is provided with a bypass diode attached thereto in parallel and connected mutually in series, a thin-film solar cell module of high voltage output can be achieved, while ensuring its hotspot resistance. This is because the bypass diode, being attached in parallel, works at the time of the occurrence of hotspot to almost short-circuit the output of the block, thereby preventing influence of the other blocks.

Furthermore, cell string dividing grooves 8 running in the vertical direction of FIG. 17(a) are formed in the cell string 10 produced in that way to divide the cell string 10 to a plurality of pieces in the transverse direction of FIG. 17, thereby forming unit cell strings 10a. Here, the division to the unit cell strings is performed to hold power generation per unit cell string 10a to a certain value or lower for improvement of the hotspot resistance. The smaller output Pa of the unit cell strings 10a is, the better, in terms of prevention of damages to the cells due to a hotspot phenomenon. The upper limit of the output Pa of the unit cell strings is obtained by a cell hotspot resistance test to be described later, which is 12 W. The output Pa of the unit cell strings can be calculated according to the following formula (4):

Pa=(P/S)×Sa (4)

where P is an output from the thin-film solar cell module

S is the area of the effective power generation region of the thin-film solar cell module; and

Sa is the area of the unit cell strings 10a.

In order to lower output Ps of the unit cell strings 10a when output P of the thin-film solar cell module is constant, the number of unit cell strings 10a included in the thin-film solar cell module needs to be increased, that is, the number of string dividing grooves 8 needs to be increased. The more the number of parallel division stages is, the more advantageous, when considering only the upper limit of the output Ps of the unit cell strings 10a. However, when the number of parallel division stages is increased, power density applied to the contact lines (P−Ps)/Sc increases, and the contact lines 5c become likely to be damaged for the following reasons (1) to (3). Here, P is the output of the thin-film solar cell module, Ps is the output possible from the cell string in shade, and Sc is the area of the contact lines 5c.

(1) Increase of Power Applied from the Other Unit Cell Strings

When one unit cell string 10a is in shade, power generated in all the other cell strings is applied to the unit cell string 10a in shade. The value of the power applied to the unit cell string 10a in shade is (P−Ps). When the number of parallel divisions is increased to reduce the output Pa of the unit cell string 10a, the power to be applied to the unit cell string 10a in shade increases, because the smaller the value of the output Pa of the unit cell string 10a is, the larger the value of the (P−Ps) is.

(2) Decrease of Contact Line Area

When the number of parallel divisions is increased, a length L of the contact lines 5c illustrated in FIG. 17(b) is shortened, and, as a result, an area Sc of the contact lines 5c is made smaller. As a result, the value of resistance of the contact lines 5c increases.

(3) Increase of Applied Power Density in Connection Grooves

As described above, the value of the (P−Ps) increases, and the area Sc of the contact P lines is made smaller, when the number of parallel divisions is increased. Therefore, the power density (P−Ps)/Sc applied to the contact lines 5c increases, and the contact lines 5c become likely to be damaged.

In order to prevent damage of the contact lines 5c, it is necessary to hold the power density (P−Ps)/Sc applied to the contact lines 5c to the upper limit thereof or lower. The upper limit of the power density (P−Ps)/Sc applied to the contact lines 5c can be determined according to the reverse overcurrent resistance test to be described later, which was 10.7 (kW/cm²). The power density (P−Ps)/Sc applied to the contact lines is not limited in particular as long as it is 10.7 (kW/cm²) or less.

Here, a cell hotspot resistance test will be described. At first, the first thin-film solar cell modules are produced and a reverse voltage of 5 V to 8 V is applied thereto, and the modules are measured for I-V and the current obtained when the reverse current is varied from 0.019 mA/cm² to 6.44 mA/cm² (referred to as RB current). Out of the measured samples, samples having different reverse currents are divided in parallel so that the output of the string to be evaluated is 5 to 50 W. Then, a hotspot resistance test is performed on a thin-film solar cell element (one cell). The hotspot resistance test was in accordance with ICE 61646, 1st EDITION. Here, however, the acceptance line was made severer by 10% in terms of an aim to make the appearance better.

As for the peeled area, the area of a region where a film is peeled off was measured by photographing the sample surface from the substrate side of the thin-film solar cell module. Results of the measurement on the samples having different cell string outputs or RB currents have revealed that cases of moderate RB currents (0.31 to 2.06 mA/cm²) are prone to peel-off of a film. It has been also revealed that the peeled area can be held to 5% or less regardless of the magnitude of the RB current, when the output of the cell string is 12 W or less. Thus, the output Ps of the unit cell string was set to 12 W or less.

Next, the reverse overcurrent resistance test will be described.

At first, the first thin-film solar cell modules were produced, and the reverse overcurrent resistance test was performed by applying an overcurrent in a direction opposite to the direction of the power generation current and examining damage of the contact lines. According to the provisions of IEC 61730, the current to be applied here should be 1.35 times the anti-overcurrent specification value, and was set to 5.5 A at 70 V here.

When the above-specified voltage and current are applied to the thin-film solar cell module, the current is divided to be applied to the cell strings connected in parallel. However, the current is not divided equally, because the value of resistance varies from cell string to cell string. In the worst case, all the 5.5 A at 70 V may be applied to one cell string. It is necessary to perform the test to see whether or not the cell string is damaged even in the worst case. Therefore, samples were produced with the width of the contact lines changed to 20 μm and 40 μm and the length of the contact lines changed to 8.2 mm to 37.5 cm to judge damage of the contact lines by visual inspection. As a result, it has been revealed that the area of the contact lines should be 20 μm×18 cm or 40 μm×9 cm=0.036 cm² or more. The power applied to the cell strings is 385 W, which leads to 385 W÷0.036 cm²=10.7 (kW/cm²).

After the string dividing grooves 8 are formed as described above, the cell string 10 is divided into two, upper and lower, regions by using a metal electrode 7. Specifically, a current-collecting electrode 7a is attached to the upper end in FIG. 17 and a current-collecting electrode 7b is attached to the lower end in FIG. 17, and the unit cell strings divided by the dividing grooves 8 running in the vertical direction are connected in parallel again. At the same time, a current-collecting electrode 7c for taking a center line is added between the two current-collecting electrodes 7a and 7b, dividing as a border the unit cell strings 10a into two, upper and lower, regions. Thereby, this integrated substrate 1 is divided to 12×2=24 regions. The current-collecting electrode 7c for taking a center line may be attached directly onto the second electrode 7 of the cell string as illustrated in FIG. 17(b). Alternatively, a space for an electrode for taking a center line may be provided between the upper region and the lower region for the attachment of the current-collecting electrode 7c.

FIG. 18 illustrates a circuit diagram of this thin-film solar cell module as a whole. Unit cell strings having a plurality of thin-film solar cell elements connected in series are connected to bypass diodes in parallel. Specifically, bypass diodes 12 are prepared in a terminal box 11, and lead wires 14, 15, and 16 led out of each unit cell string 10a are arranged there to connect two cell strings to two bypass diodes 12 in parallel. Since the two bypass diodes 12 are connected in series, a plurality of cell strings are connected in series in a direction in which the plurality of thin-film solar cell elements are connected in series. Thereby, the number of series connections in the unit string can be held to the number of stages specified in the formula (1) or less and, at the same time, a two-fold voltage can be outputted between terminals 13.

While each unit cell string is connected within the terminal box 11 in the above-described first solar cell module, it may be connected onto a supporting substrate 1 of the thin-film solar cell module by providing and using a wire. In this case, the wire provided on the supporting substrate 1 may be formed at the same time as the formation of the current-collecting electrode 7, or a separate wire such as a jumper wire may be used.

When a three-junction type cell in which two amorphous silicon cells and one microcrystalline silicon cell are laminated is used for the photoelectric conversion layer in the configuration of the first thin-film solar cell string, the calculation shown in the formula (1) will be as follows:

Rshm=4000 [Ω]

Vpm=1.80 [V]

Ipm=62 [mA]

n<Rshm÷2.5÷Vpm×Ipm+1=56.1

Therefore, since n needs to be 56 stages or less according to the formula (1), the first thin-film solar cell module is provided with the current-collecting electrode 7c for taking a center in the middle of its series structure of 106 stages, and each unit cell string 10a is of 53 stages.

In addition, while the first thin-film solar cell module has one current-collecting electrode 7c for taking a center, the number of lines for taking a center may be increased by increasing the number of divisions according to the number of integration stages of the substrate as a whole and individual cell voltage so that the number of integration stages per region is decreased. Furthermore, one block is acceptable when the output voltage is equal to or lower than the voltage to be obtained according to the number of stages of the formula (1).

<Second thin-film solar cell module>-Embodiment of 53 stages ×6 parallels×4 blocks in series-

The second thin-film solar cell module is characterized in a connection method after division in order to output a higher voltage. More specifically, when the cell string is divided to 12 unit cell strings by the cell string dividing grooves 8, the middle string dividing groove 8 is made wider. Since a high voltage equivalent to half of the thin-film solar cell module operation voltage is applied to this part during power generation, it is necessary to ensure a breakdown voltage. In the second thin-film solar cell module, the string dividing groove 8a is approximately twice as wide as the other string dividing grooves 8. It is needless to say that the string dividing groove 8a may be filled with a resin, or an insulation film may be formed to increase a withstand voltage.

Thereafter, current-collecting electrodes 7a, 7b, and 7c are formed separately so that each of them is divided into one for the cell string on the right and one for the cell string on the left to be independent electrodes. Thereby, four blocks of 53 stages of series connection×6 parallels are completed. The blocks form a 4-block series connection. Thus, a thin-film solar cell module outputting a further voltage twice the voltage of the first thin-film solar cell module can be achieved. In other words, an output voltage that is 4 times that of one cell string is obtained.

<Third thin-film solar cell module>-Embodiment of 48 stages×5 parallels×4 blocks in series achieved by using two substrates of 48 stages×5 parallels×2 blocks in series-

As for the first and second thin-film solar cell strings, the supporting substrate itself is large, and have been described examples of the thin-film solar cell module in which all cell strings are formed on the substrate. However, a plurality of small supporting substrates are combined to each other to make it possible to form a large solar cell module. In that case, a module of high voltage can be produced while ensuring reliability by forming cell strings in respective supporting substrates so that the requirement shown in the formula (1) is met and connecting the cell strings together. That is, the cell strings are formed in the same manner as in the first and second thin-film solar cell modules, and the supporting substrates 1 of the two thin-film solar cell module are mounted on an integrated substrate formed of one cover glass, and configured to be integrated together. And, they are connected in series in the terminal box 11.

The above-described small supporting substrates may be sealed separately to be integrated on the larger integrated substrate, or may be integrated by using a frame. Or, the two small supporting substrates may be mounted on one integrated substrate and sealed to be integrated together.

Or, the two supporting substrates may be sealed separately and integrated with the use of a frame to form one thin-film solar cell module.

The solar cell modules for outputting high voltages are described above, and, next, solar cell modules for outputting low voltages will be described.

<Fourth thin-film solar cell module>-Embodiment of 20 stages×12 parallels×1 block-

The thin-film solar cell module 10 outputs a low voltage and the stage number of a connection in-series is 20 and the arrays of 12 parallels are structured. The other construction is the same as the first thin-film solar cell module.

The first to fourth thin-film solar cell modules as above mentioned are described as a thin-film solar cell module of a super straight structure. However, a thin-film solar cell module of a substrate structure is also applicable. In that case, the second electrode, the photoelectric conversion layer, and the first electrode are formed on the substrate in this order.

In addition, while the above-described first to fourth thin-film solar cell modules are each provided with one terminal box, they may be each provided with a plurality of terminal boxes, and a plurality of terminal boxes may be wired to connect the cell strings in series.

Furthermore, as for the above-described first to fourth thin-film solar cell modules, two cell strings are formed and divided into two; however, one cell string may be acceptable when the output voltage is satisfiable by the number of stages n of the cell strings. Moreover, the number of cell strings does not need to be an even number, and may be an odd number.

In addition, as for the above-described first to fourth thin-film solar cell modules, the cell strings are connected in series through the connection to the bypass diodes; however, the cell strings may be directly connected without using the bypass diodes, and the cell strings may be connected to resistors and loads but the bypass diodes.

### Embodiment 2

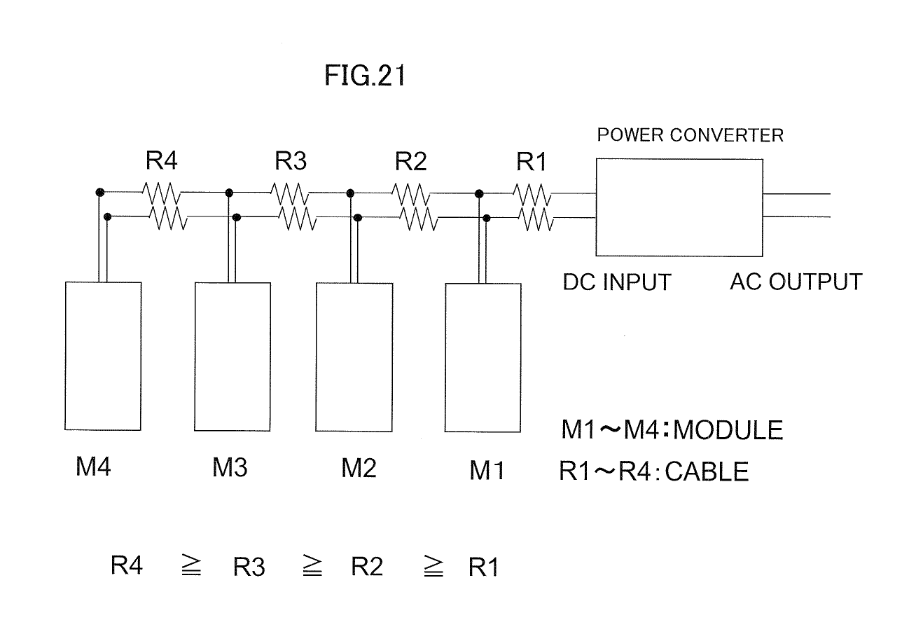

FIG. 21 is a block diagram of Embodiment 2 of the solar power generation system. As illustrated in FIG. 21, resistors R1, R2, R3 and R4 are connected between the trunk lines 101 and 102 with which the thin film solar cell strings are connected in parallel. The resistors R1, R2, R3 and R4 are connected such that the closer the resistors R1, R2, R3 and R4 are to the DC/AC converter 122, the smaller the value of resistance is. The resistors R1, R2, R3 and R4 can be formed with internal resistances of the trunk lines 101 and 102. The resistors R1, R2, R3 and R4 are connected to each of the trunk lines 101 and 102 in FIG. 21, but either one of the trunk lines 101 and 102 may be all right. When the resistors R1, R2, R3 and R4 are formed with the internal resistances of the trunk lines 101 and 102, the thickness or the number of the trunk lines 101 and 102 may be changed as necessary. The resistors R1, R2, R3 and R4 equalize the voltages at an input terminal of the DC/AC converter IN.

The other configurations are the same as those of Embodiment 1. The first to fourth thin-film solar cell modules forming the thin-film solar cell modules are also the same as those of Embodiment 1.

### Embodiment 3

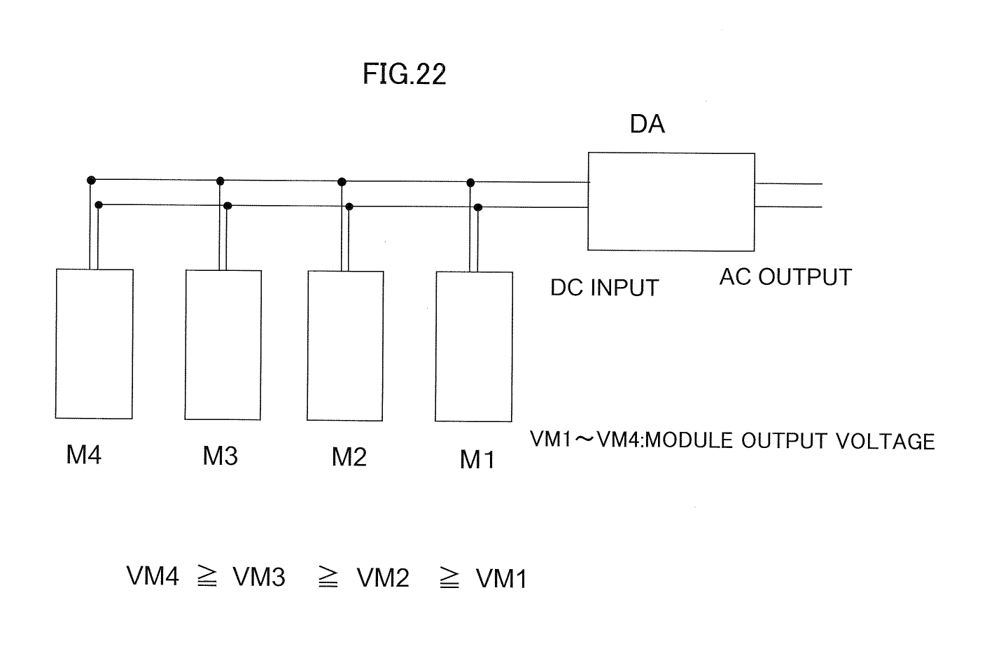

FIG. 22 is a block diagram of Embodiment 3 of the solar power generation system. As illustrated in FIG. 22, the output voltages of a plurality of thin-film solar cell strings are higher as they are further from a DC/AC converter 122 and lower as they are closer to the DC/AC converter 122. And, the voltages are equalized at an input terminal of the DC/AC converter 122. When the plurality of thin-film solar cell strings have uneven output voltages, they may be arranged in order of output voltages so that the thin-film solar cell strings having a lower output voltage is at the input terminal of the DC/AC converter IN.

The other configurations are the same as those of Embodiment 1. The first to third thin-film solar cell modules forming the thin-film solar cell strings are also the same as those of Embodiment 1.

As for Embodiments 1 to 3, examples have been described in which a DC/AC converting circuit is used as a power converter. However, the effects of the present invention are not limited to the DC/AC converting circuit. For example, when a power converting circuit is used, the same effects as described above can be obtained.

In the solar power generation system of the present invention, in a configuration including a blocking diode, a short-circuit fault in a solar cell string and an open-circuit fault in a overcurrent protecting device can be easily detected as described below.

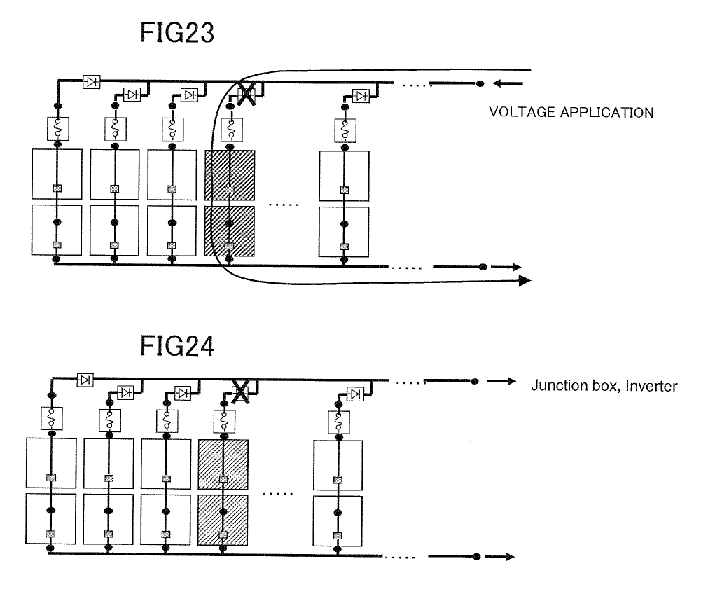

FIG. 23 shows a case in which a short-circuit fault in a blocking diode is detected in a solar cell string in which a overcurrent protecting device is not disconnected. The blocking diodes 141 are connected to a plus electrode side of the two solar cell modules 111 and 112 connected in series. A voltage is applied to the plus electrode side in such a condition that the solar cell modules are not exposed to light such as at night in the solar power generation system. Hence, a current can flow through the solar cell module whose blocking diode in failure is short circuited to thereby heat the solar cell module. The temperature of the heated solar cell module is higher several degrees than the other solar cell modules. An observation using a thermograph or the like enables the detection of the distinction between the heated solar cell and the other solar cell modules to identify the position of the heated solar cell module. The effect of observing using the thermograph and detecting the failure is effective for the solar power generation system of the present invention including a number of solar cell modules connected in parallel. It is especially effective for the case where the number of the in-series connection is as little as about 2 to 10 and the number of the in-parallel connection is as great as about several tens. Thus, a voltage is applied from the trunk lines to observe the heat generation of the solar cell modules in order to enable the examination of a failure of the blocking diodes.

FIG. 24 shows a case in which an open-circuit failure of a blocking diode in a solar cell string in which an overcurrent protecting device is not disconnected is detected, in which the blocking diodes 141 are coupled to a plus electrode side of the two solar cell modules 111 and 112 connected in series. The inverter 122 is operated in the daytime in the solar generation system. Hence, the solar cell module whose blocking diode 141 in failure is open-circuited is heated higher than the heat temperature of the other solar cell modules. That is, the solar cell modules that are ordinarily operated are heated by a power generation current, but the solar cell module whose blocking diode is open-circuited in failure is heated without flowing the power generation current to be correspondingly at a higher temperature. The temperature of the heated solar cell module is higher several degrees than the other solar cell modules. An observation using a thermograph or the like enables the detection of the distinction between the heated solar cell and the other solar cell modules. The effect of observing using the thermograph and detecting the failure is effective for the solar power generation system of the present invention including a number of solar cell modules connected in parallel. It is especially effective for the case where the number of the in-series connection is as little as about 2 to 10 and the number of the in-parallel connection is as great as about several hundreds. Since these phenomena are caused in the case where the solar cell modules are damaged, this method can be used to detect the failure of the solar cell modules.

### DESCRIPTION OF REFERENCE SIGNS

101, 102 Trunk line

111, 112, 113 Thin-film solar cell module

121 Solar cell string

122 Junction box

122a Fuse

131 Branch line

133 Power converter

134 Overcurrent protecting device

134a Overcurrent protecting element (fuse)

135 Connector

141 Branch connection unit

141a Blocking diode

213 Base

214 Support post

1342, 1351 Plug

1341, 1352 Socket

230 Abnormality detecting unit

232 Signal circuit

233 Oscillation circuit

234 Transmission circuit

235 Antenna

1. A solar power generation system comprising:
an electric power extracting trunk line having a plurality of branch lines interconnected in parallel;
solar cell modules or solar cell strings connected to the branch lines; and
overcurrent protecting devices to which overcurrent protecting elements fusible by overcurrents flowing in the solar cell strings or the branch lines are connected between the branch lines and the solar cell modules or to parts of the solar cell strings.

2. The solar power generation system according to claim 1, wherein the solar cell strings are aligned and installed to make it possible to visually check the overcurrent protecting devices from the outside.

3. The solar power generation system according to claim 1, wherein each of the overcurrent protecting devices includes a fuse that is disconnected when a current not less than a predetermined current flows in the corresponding branch line, and the disconnection of the fuse can be visually checked.

4. The solar power generation system according to claim 1, wherein each of the overcurrent protecting device has a vessel, and a color fixing agent or a temperature-sensitive agent is sealed in the vessel.

5. The solar power generation system according to claim 1, wherein, wherein each of the overcurrent protecting devices
includes heat-sensitive paper wound thereon such that the heat-sensitive paper can be seen from the outside.

6. The solar power generation system according to claim 1, wherein each of the overcurrent protecting devices is replaceably connected by a socket and a plug connected to the branch line.

7. The solar power generation system according to claim 1, wherein each of the overcurrent protecting devices is installed at an almost eye level on a rear surface side of solar cell panel.

8. The solar power generation system according to claim 1, further comprising an abnormality detecting unit that is operated by an electric power generated by a solar cell string and detects abnormality of the overcurrent protecting device, wherein, when the solar cell string and the overcurrent protecting device are normal, the abnormal detecting unit periodically establishes communication, and, when the solar cell string or the overcurrent protecting device is abnormal, the abnormality detecting unit is not allowed to establish communication.

9. The solar power generation system according to claim 1, wherein the solar cell string is configured by a thin-film solar cell element.

10. Power lines for solar power generation system with which a plurality of solar cell strings are interconnected in parallel, comprising:
a power extracting trunk line having a plurality of branch lines interconnected in parallel; and
an overcurrent protecting device to which an overcurrent protecting elements fusible by overcurrents flowing in the branch lines is connected at at least one end of the branch line.
